(19) United States
(12) Patent Application Publication
(10) Pub. No.: US 2024/0248237 A1
(43) Pub. Date: Jul. 25, 2024

(54) METASURFACE HAVING A STEPPED SUBSTRATE, METHODS OF DESIGNING AND PROCESSING THE SAME, AND OPTICAL LENS

(71) Applicant: SHENZHEN METALENX TECHNOLOGY CO.,LTD, Shenzhen (CN)

(72) Inventors: Chenglong HAO, Shenzhen (CN); Fengze TAN, Shenzhen (CN); Jian ZHU, Shenzhen (CN)

(73) Assignee: SHENZHEN METALENX TECHNOLOGY CO.,LTD, Shenzhen (CN)

(21) Appl. No.: 18/599,112

(22) Filed: Mar. 7, 2024

Related U.S. Application Data
(63) Continuation of application No. PCT/CN22/97819, filed on Jun. 9, 2022.

(30) Foreign Application Priority Data
Sep. 30, 2021 (CN) 202111166673.0

(51) Int. Cl. G02B 1/00; G02B 27/00; G03F 7/00

(52) U.S. Cl. CPC G02B 1/002; G02B 27/0012; G03F 7/0005; G03F 7/0035; G03F 7/70416

(57) ABSTRACT

Provided are a metasurface having a stepped substrate, methods of designing and processing the metasurface, and an optical lens. The metasurface includes the stepped substrate and nanostructures. The stepped substrate includes a plurality of positions for phase design that are configured to modulate a phase of incident light, and substrate heights of two adjacent positions for phase design are different; substrate heights of respective positions for phase design are related to functions of the metasurface. The nanostructures are respectively arranged at the respective positions for phase design.

### CROSS-REFERENCE TO RELATED APPLICATION

This application is a continuation of International Patent Application of PCT application serial No. PCT/CN2022/097819, filed on Jun. 9, 2022, which claims the benefit of priority from China Application No. 202111166673.0, filed on Sep. 30, 2021. The content of the aforementioned applications, including any intervening amendments thereto, are incorporated herein by reference.

### TECHNICAL FIELD

The present disclosure relates to the simulation and the design of a metasurface with a substrate, in particular to a metasurface having a stepped substrate, methods of designing and processing the same and an optical lens.

### BACKGROUND

Currently, a metasurface with a stepped substrate has been continuously garnering attention in both scientific and industrial fields. In the related art, the existing metasurface with the stepped substrate must be manufactured on a curved substrate. However, it is not feasible to process curved surfaces by the existing semiconductor processes. Compared to the processing of flat surfaces, the processing of the curved surfaces is more complex. Thus, the existing metasurface with the stepped substrate based on the existing process is not suitable for mass production.

### SUMMARY

In view of the above technical problems, a metasurface having a stepped substrate, methods of designing and processing the metasurface, and an optical lens are provided according to embodiments of the present disclosure.

In a first aspect, the present embodiment provides a metasurface having a stepped substrate. The metasurface includes the stepped substrate and nanostructures.

The stepped substrate includes a plurality of positions for phase design that are configured to modulate a phase of incident light, and substrate heights of two adjacent positions for phase design are different; substrate heights of respective positions for phase design are related to functions of the metasurface.

The nanostructures are respectively arranged at the respective positions for phase design.

In a second aspect, the present embodiment provides a method of processing a metasurface having a stepped substrate. The method is configured to process the metasurface having the stepped substrate of the first aspect. The method includes:
performing grayscale lithography on a planar substrate to obtain the stepped substrate;
depositing a structural layer on the stepped substrate, where a ratio of a first structural layer thickness to a second structural layer thickness is less than 1/5 in a process of depositing the structural layer, where the first structural layer thickness refers to a thickness of the structural layer along sidewalls of the stepped substrate, and the second structural layer thickness refers to a thickness of the structural layer at a bottom of the stepped substrate;
coating a photoresist layer on the structural layer;
exposing and developing the photoresist layer to form a relief sculpture on the stepped substrate;
performing etching and removing remaining photoresists, so as to form the nanostructures and obtain the metasurface having the stepped substrate.

In a third aspect, the present embodiment provides a method of designing a metasurface having a stepped substrate. The method includes:
obtaining an operating wavelength range of the metasurface which is configured to generate a target optical lens;
according to the operating wavelength range, determining a material of the stepped substrate and a material of nanostructures, where the stepped substrate and the nanostructures form the metasurface;
selecting any wavelength from the operating wavelength range as a main wavelength of the operating wavelength range;
based on the main wavelength, calculating a shape and a size of the stepped substrate and determining the nanostructures in the metasurface;
based on the material of the stepped substrate and the material of the nanostructures, the calculated shape and the calculated size of the stepped substrate, a shape and a size of the nanostructures, forming the metasurface having the stepped substrate;
performing a full-wave simulation of the metasurface having the stepped substrate to obtain a simulation result;
when the simulation result shows that the metasurface having the stepped substrate is capable of realizing functions of the target optical lens, determining that the metasurface having the stepped substrate meets functional requirements of the target optical lens.

In a fourth aspect, the present embodiment provides a device for designing a metasurface having a stepped substrate. The device includes:
an acquisition module, configured to obtain an operating wavelength range of the metasurface which is configured to generate a target optical lens; and configured to determine materials of the stepped substrate and nanostructures used to form the metasurface according to the operating wavelength range; and configured to select any wavelength from the operating wavelength range as a main wavelength of the operating wavelength range;
a first determination module, configured to calculate a shape and a size of the stepped substrate and determine the nanostructures in the metasurface based on the main wavelength;
a processing module, configured to form the metasurface having the stepped substrate based on the material of the stepped substrate and the material of the nanostructures, the calculated shape and the calculated size of the stepped substrate, a shape and a size of the nanostructures;
a simulation module, configured to perform a full-wave simulation of the metasurface having the stepped substrate to obtain a simulation result;
a second determination module, configured to determine that the metasurface having the stepped substrate meets functional requirements of the target optical lens when the simulation result shows that the metasurface having the stepped substrate is capable of realizing functions of the target optical lens.

In a fifth aspect, the present embodiment provides a non-transitory computer-readable storage medium in which a computer program is stored, where the computer program is executed by a processor, so as to implement the method of designing the metasurface having the stepped substrate of the third aspect.

In a sixth aspect, the present embodiment provides an electronic device. The electronic device provides a memory, a processor and at least one program, where the at least one program is stored in the memory and is configured to be executed by the processor, so as to implement the method of designing the metasurface having the stepped substrate of the third aspect.

In a seventh aspect, the present embodiment provides an optical lens, including the metasurface having the stepped substrate of the first aspect.

In the technical solutions of the first aspect, the second aspect and the seventh aspect, a metasurface including a stepped substrate and nanostructures is provided. The stepped substrate includes a plurality of positions for phase design that are different in substrate height and are configured to modulate a phase of incident light. The nanostructures are respectively arranged at the respective positions for phase design, such that the designed metasurface having the stepped substrate can achieve the same function of the metasurface having the curved substrate, at the same time, be thinner than the metasurface having the curved substrate. Respective positions for phase design are planes with different substrate heights. Thus, unlike the metasurface having the curved substrate which must be processed by a complex processing technology, the metasurface with the stepped substrate can be processed simply by the existing semiconductor planar processing technology, in other words, the processing of the metasurface with the stepped substrate is much simpler than the processing of the metasurface with the curved substrate, thus, it is easier to implement the mass production and the promotion of the metasurface with the stepped substrate. An appearance of the processed metasurface having the stepped substrate is almost the same as an appearance of the designed metasurface having the stepped substrate, displaying a small morphological difference.

In the technical solutions of the third aspect, the fifth aspect and the sixth aspect, it is achievable to execute steps of obtaining an operating wavelength range of the metasurface which is configured to generate a target optical lens; according to the operating wavelength range, determining a material of the stepped substrate and a material of nanostructures, where the stepped substrate and the nanostructures form the metasurface; selecting any wavelength from the operating wavelength range as a main wavelength of the operating wavelength range; based on the main wavelength, obtaining a shape and a size of the stepped substrate and determining the nanostructures in the metasurface; based on the material of the stepped substrate and the material of the nanostructures, the calculated shape and the calculated size of the stepped substrate, a shape and a size of the nanostructures, forming the metasurface having the stepped substrate; performing a full-wave simulation of the metasurface having the stepped substrate to obtain a simulation result; when the simulation result shows that the metasurface having the stepped substrate is capable of realizing functions of the target optical lens, determining that the metasurface having the stepped substrate meets functional requirements of the target optical lens. Whereby, a metasurface having a stepped substrate that is capable of realizing the target functions is obtainable according to the functional requirements of the target optical lens. In addition, the metasurface having the stepped substrate can be approximately assumed as including a plurality of planar substrate, and thus it is feasible to process the metasurface of the present embodiment by the existing semiconductor planar processing technology, being suitable for mass production.

It should be understood that, the foregoing general descriptions and the following detailed descriptions are merely for exemplary and explanatory purposes and are not intended to limit the present disclosure.

### BRIEF DESCRIPTION OF THE DRAWINGS

In order to explain embodiments of the present disclosure or the prior art more clearly, drawings used in the description of the embodiments or the prior art will be briefly explained below. Obviously, the following drawings are merely for exemplary and explanatory purposes. It is understood by those skilled in the art that without paying any creative efforts, other drawings are available based on the following drawings.

FIG. 1 schematically shows a structural diagram of a metasurface having a curved substrate.

FIG. 2 schematically shows a first structural diagram of a metasurface having a stepped substrate according to Embodiment 1 of the present disclosure.

FIG. 3a schematically shows a second structural diagram of a metasurface having a stepped substrate according to Embodiment 1 of the present disclosure.

FIG. 3b schematically shows a third structural diagram of a metasurface having a stepped substrate according to Embodiment 1 of the present disclosure.

FIG. 4a is a schematic diagram of a circular nanopillar in the metasurface according to Embodiment 1 of the present disclosure.

FIG. 4b is a schematic diagram of a rectangular nanopillar in the metasurface according to Embodiment 1 of the present disclosure.

FIG. 4c is a schematic diagram of a hollow circular nanopillar in the metasurface according to Embodiment 1 of the present disclosure.

FIG. 4d is a schematic diagram of a hollow square nanopillar in the metasurface according to Embodiment 1 of the present disclosure.

FIG. 4e is a schematic diagram of a nanopillar having a cavity structure with a regular square prism shape in the metasurface according to Embodiment 1 of the present disclosure.

FIG. 4f is a schematic diagram of a nanopillar having a cylindrical cavity structure in the metasurface according to Embodiment 1 of the present disclosure.

FIG. 5 depicts a flow chart of a method of processing a metasurface having a stepped substrate according to Embodiment 2 of the present disclosure.

FIG. 6 depicts a flow chart of a method of designing a metasurface having a stepped substrate according to Embodiment 3 of the present disclosure.

FIG. 7 schematically depicts a structural diagram of a device for designing a metasurface having a stepped substrate according to Embodiment 4 of the present disclosure.

FIG. 8 schematically depicts a structural diagram of an electronic device according to Embodiment 5 of the present disclosure.

FIG. 9 shows phases of respective positions on a stepped substrate for modulating light with different wavelengths as a function of substrate heights of a converging lens designed according to a method of designing a metasurface having the stepped substrate as provided in Embodiment 3 of the present disclosure.

FIG. 10a is a schematic diagram showing actual phases of nanostructures and required phases of a converging lens when a main wavelength is set to be 8 μm, where the converging lens is designed according to a method of designing a metasurface having a stepped substrate as provided in Embodiment 3 of the present disclosure.

FIG. 10b is a schematic diagram showing actual phases of nanostructures and required phases of a converging lens when a main wavelength is set to be 10 μm, where the converging lens is designed according to a method of designing a metasurface having a stepped substrate as provided in Embodiment 3 of the present disclosure.

FIG. 10c is a schematic diagram showing actual phases of nanostructures and required phases of a converging lens when a main wavelength is set to be 12 μm, where the converging lens is designed according to a method of designing a metasurface having a stepped substrate as provided in Embodiment 3 of the present disclosure.

FIG. 11 shows substrate heights of a diverging lens without chromatic aberration and spherical aberration designed according to a method of designing a metasurface having a stepped substrate as provided in Embodiment 3 of the present disclosure.

FIG. 12a shows an achromatic phase of a diverging lens without chromatic aberration and spherical aberration when a main wavelength is set to be 8 μm, where the diverging lens is designed according to a method of designing a metasurface having a stepped substrate as provided in Embodiment 3 of the present disclosure.

FIG. 12b shows an achromatic phase of a diverging lens without chromatic aberration and spherical aberration when a main wavelength is set to be 10 μm, where the diverging lens is designed according to a method of designing a metasurface having a stepped substrate as provided in Embodiment 3 of the present disclosure.

FIG. 12c shows an achromatic phase of a diverging lens without chromatic aberration and spherical aberration when a main wavelength is set to be 12 μm, where the diverging lens is designed according to a method of designing a metasurface having a stepped substrate as provided in Embodiment 3 of the present disclosure.

FIG. 13a is a schematic diagram showing actual phases of nanostructures and required phases of a diverging lens without chromatic aberration and spherical aberration when a main wavelength is set to be 8 μm, where the diverging lens is designed according to a method of designing a metasurface having a stepped substrate as provided in Embodiment 3 of the present disclosure.

FIG. 13b is a schematic diagram showing actual phases of nanostructures and required phases of a diverging lens without chromatic aberration and spherical aberration when a main wavelength is set to be 10 μm, where the diverging lens is designed according to a method of designing a metasurface having a stepped substrate as provided in Embodiment 3 of the present disclosure.

FIG. 13c is a schematic diagram showing actual phases of nanostructures and required phases of a diverging lens without chromatic aberration and spherical aberration when a main wavelength is set to be 12 μm, where the diverging lens is designed according to a method of designing a metasurface having a stepped substrate as provided in Embodiment 3 of the present disclosure.

FIG. 14 is a structural diagram of a refractive-meta hybrid optical system for forming a phase correction plate, where the phase correction plate is designed according to a method of designing a metasurface having a stepped substrate as provided in Embodiment 3 of the present disclosure.

FIG. 15 shows substrate heights of a phase correction plate formed by a refractive-meta hybrid optical system, where the phase correction plate is designed according to a method of designing a metasurface having a stepped substrate as provided in Embodiment 3 of the present disclosure.

FIG. 16a shows an achromatic phase of a phase correction plate formed by a refractive-meta hybrid optical system when a main wavelength is set to be 8 μm, where the phase correction plate is designed according to a method of designing a metasurface having a stepped substrate as provided in Embodiment 3 of the present disclosure.

FIG. 16b shows an achromatic phase of a phase correction plate formed by a refractive-meta hybrid optical system when a main wavelength is set to be 10 μm, where the phase correction plate is designed according to a method of designing a metasurface having a stepped substrate as provided in Embodiment 3 of the present disclosure.

FIG. 16c shows an achromatic phase of a phase correction plate formed by a refractive-meta hybrid optical system when a main wavelength is set to be 12 μm, where the phase correction plate is designed according to a method of designing a metasurface having a stepped substrate as provided in Embodiment 3 of the present disclosure.

FIG. 17a is a schematic diagram showing actual phases of nanostructures and required phases of a phase correction plate formed by a refractive-meta hybrid optical system when a main wavelength is set to be 8 μm, where the phase correction plate is designed according to a method of designing a metasurface having a stepped substrate as provided in Embodiment 3 of the present disclosure.

FIG. 17b is a schematic diagram showing actual phases of nanostructures and required phases of a phase correction plate formed by a refractive-meta hybrid optical system when a main wavelength is set to be 10 μm, where the phase correction plate is designed according to a method of designing a metasurface having a stepped substrate as provided in Embodiment 3 of the present disclosure.

FIG. 17c is a schematic diagram showing actual phases of nanostructures and required phases of a phase correction plate formed by a refractive-meta hybrid optical system when a main wavelength is set to be 12 μm, where the phase correction plate is designed according to a method of designing a metasurface having a stepped substrate as provided in Embodiment 3 of the present disclosure.

FIG. 18a is a schematic diagram of a nanostructure database used in a method of designing a metasurface having a stepped substrate as provided in Embodiment 3 of the present disclosure.

FIG. 18b is a schematic diagram of a nanostructure database used in a method of designing a metasurface having a stepped substrate as provided in Embodiment 3 of the present disclosure.

### DETAILED DESCRIPTION OF DISCLOSURED EMBODIMENTS

It should be understood that terms used in the present disclosure, such as “central”, “longitudinal”, “transverse”, “length”, “width”, “thickness”, “upper”, “lower”, “front”, “rear”, “left”, “right”, “vertical”, “horizontal”, “top”, “bottom”, “interior”, “exterior”, “clockwise”, “counterclockwise” which are intended to indicate orientational or positional relationships based on the accompanying drawings are only for the purpose of describing the present disclosure conveniently and simply, and are not intended to indicate or imply a particular orientation, a structure and an operation in a particular orientation of the device or element referred to herein, and thus are not to be interpreted as a limitation to the present disclosure.

In addition, terms “first” and “second” are used for descriptive purposes, and are not intended to indicate or imply relative importance or implicitly indicate the quantity of the indicated technical features. Therefore, features defined by “first” or “second” may explicitly or implicitly include one or more of these features. In the description of the present disclosure, “plurality” or “multiple” means that there are two or more of these features, unless otherwise explicitly and specifically defined.

In the present disclosure, unless otherwise clearly stated and defined, terms “assemble”, “connect”, “joint”, “fix” and the like should be understood in a broad sense. For example, these terms may be referred to as “fixedly connect”, “detachably connect”, or “integrally connected”; these terms may also be referred to as “mechanically connect” or “electrically connect”; these terms may be further referred to as “directly connect”, “indirectly connected by an intermediary” or “communicated between an interior of an element and an interior of another element”. It is understandable to a person having ordinary skill in the art that the terms set forth are interpreted according to specific scenarios of the present disclosure.

Currently, a metasurface with a stepped substrate has been continuously garnering attention in both scientific and industrial fields. In the related art, the existing metasurface with the stepped substrate must be manufactured on a curved substrate. However, it is not feasible to process curved surfaces by the existing semiconductor processes. Compared to the processing of flat surfaces, the processing of the curved surfaces is more complex. Thus, the existing metasurface with the stepped substrate based on the existing process is not suitable for mass production.

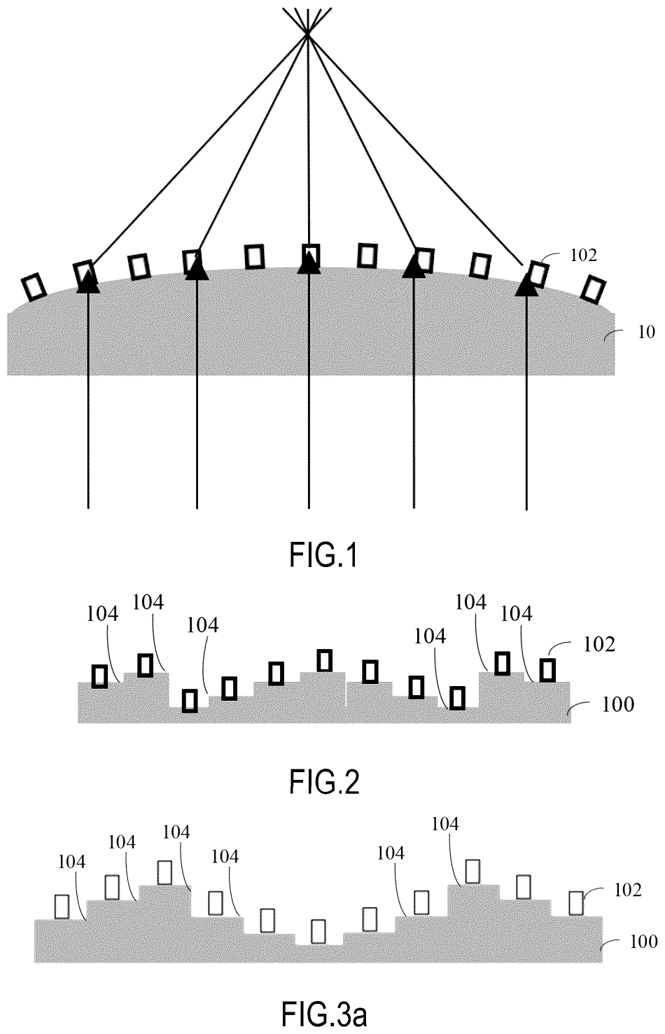

The related art provides a metasurface having a curved substrate 10, as shown in FIG. 1. Nanostructures 102 are arranged on the curved substrate 10. However, the metasurface having the curved substrate has lots of drawbacks, such as being hardly processed and being very thick.

In view of the above technical problems, this disclosure provides a metasurface having a stepped substrate, methods of designing and processing the same and an optical lens. Provided in the present embodiment is a metasurface including a stepped substrate and nanostructures. The stepped substrate includes a plurality of positions for phase design that are different in substrate height and are configured to modulate a phase of incident light. The nanostructures are respectively arranged at the respective positions for phase design, such that the metasurface having the stepped substrate is similar to the metasurface having the curved substrate in structure, and the two metasurfaces with different substrates have similar functions. However, in the present embodiment, respective positions for phase design are planes with different substrate heights. Thus, unlike the metasurface having the curved substrate which must be processed by a complex processing technology, the metasurface with the stepped substrate is processed simply by a planar processing technology, in other words, the processing of the metasurface with the stepped substrate is much simpler than the processing of the metasurface with the curved substrate, thus, it is easier to implement the mass production and the promotion of the metasurface with the stepped substrate. In addition, the metasurface with the stepped substrate can achieve the same function of the metasurface having the curved substrate, at the same time, be thinner than the metasurface having the curved substrate.

### Embodiment 1

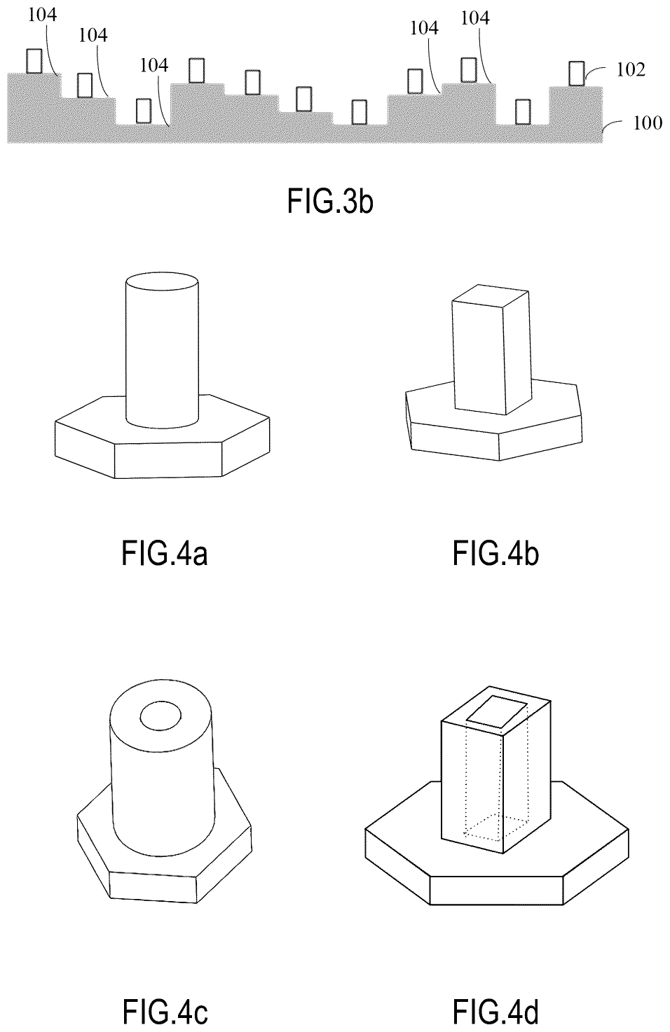

Referring to FIG. 2, FIG. 3a and FIG. 3b, a metasurface having a stepped substrate varies in profile. Provided in the present embodiment is a metasurface having a stepped substrate, including the stepped substrate 100 and nanostructures 102.

The stepped substrate 100 includes a plurality of positions 104 for phase design that are configured to modulate a phase of incident light. Substrate heights of two adjacent positions for phase design are different. Substrate heights of respective positions for phase design are related to functions of the metasurface having the stepped substrate.

The nanostructures 102 are respectively arranged at the respective positions for phase design.

FIG. 2 shows a metasurface having a stepped substrate. In an embodiment, the metasurface having the stepped substrate may serve as a converging lens that is designed to operate in a far infrared spectrum (from 8 μm to 12 μm). The converging lens is similar to a convex lens in shape.

FIG. 3a shows a metasurface having a stepped substrate. In an embodiment, the metasurface having the stepped substrate may serve as a negative achromatic lens. The negative achromatic lens is similar to a concave lens in shape.

FIG. 3b shows a metasurface having a stepped substrate. In an embodiment, the metasurface having the stepped substrate may serve as a phase correction plate formed by a refractive-meta hybrid optical system. The phase correction plate has a stepped shape.

In an embodiment, the nanostructures may have a pillar structure or a cavity structure.

The nanostructures are configured to modulate the phase of the incident light. Respective nanostructures are polarization-dependent or polarization-independent.

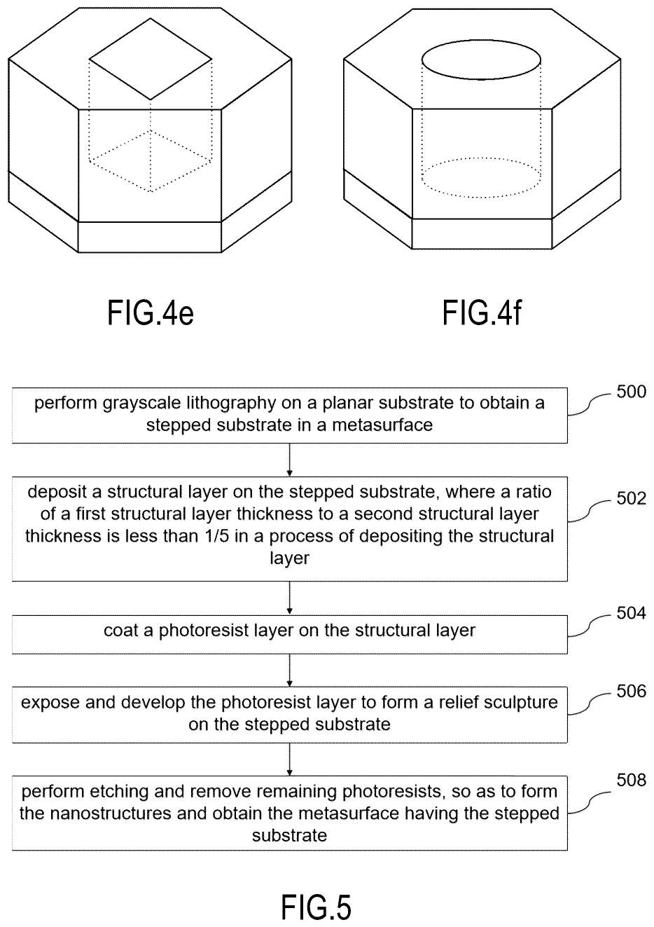

A nanostructure as shown in FIG. 4a has a cylinder shape, which is a polarization-independent nanostructure.

A nanostructure as shown in FIG. 4b has a rectangular prism shape, which is a polarization-dependent nanostructure.

A nanostructure as shown in FIG. 4c has a hollow cylinder shape, which is a polarization-independent nanostructure.

A nanostructure as shown in FIG. 4d is a square nanopillar with a hollow space, where the hollow space has a quadrangular prism shape. The square nanopillar with the hollow space is a polarization-independent nanostructure.

A nanostructure as shown in FIG. 4e has a cavity structure with a regular square prism shape. Optionally, a cylinder or a regular prism with 4n lateral edges is further provided within the cavity structure. The nanostructure having the cavity structure with the regular square prism shape is polarization-independent.

A nanostructure as shown in FIG. 4f has a cavity structure with a cylinder shape. Optionally, a cylinder or a regular prism with 4n lateral edges is further provided within the cavity structure. The nanostructure having the cavity structure with the cylinder shape is polarization-independent.

Optionally, the metasurface having the stepped substrate further includes a filler material.

The filler material is configured to fill up gaps between the nanostructures to form a flat surface, such that a film may be coated.

The filler material may be, but is not limited to, organic glass or polycarbonate.

The metasurface having the stepped substrate is covered by the filler material to form a top surface that is parallel to a bottom surface of the metasurface.

Optionally, the metasurface having the stepped substrate further includes an anti-reflection film or a protective layer.

The anti-reflection film is a thin film deposited on a surface of an optical lens and is configured to cause reflected light to destructively interfere, thereby reducing the reflection loss or increasing transmission.

The anti-reflection film may be, but is not limited to: a magnesium fluoride anti-reflection film, a titanium oxide anti-reflection film, a lead sulfide anti-reflection film, a lead selenide anti-reflection film, a ceramic infrared anti-reflection film that is designed for infrared light, or a vinyl silsesquioxane hybrid film.

The protective layer covers the metasurface having the stepped substrate for the purpose of protection.

The protective layer may be a tempered film made of organic glass.

The anti-reflection film and/or the protective layer are provided on the top surface of the filler material.

Optionally, the metasurface having the stepped substrate includes the anti-reflection film and the protective layer. The anti-reflection film is arranged on the top surface of the filler material. The protective layer is arranged on the anti-reflection film.

The metasurface having the stepped substrate shown in FIG. 2 is capable of realizing light convergence just as the metasurface having the curved substrate shown in FIG. 1 does. In addition, unlike the metasurface having the curved substrate which must be processed by a complex processing technology, the metasurface having the stepped substrate can be processed by the existing semiconductor planar processing technology, which greatly reduces the processing difficulties. Furthermore, the metasurface with the stepped substrate can achieve the same function of the metasurface having the curved substrate, at the same time, be thinner than the metasurface having the curved substrate, such that application scenarios of the metasurface having the stepped substrate become wider.

Provided in the present embodiment is an optical lens, which includes the metasurface having the stepped substrate of any embodiment as described above.

In summary, the metasurface and the optical lens as provided in the present embodiment have the stepped substrate and the nanostructures. The stepped substrate includes the plurality of positions for phase design that are different in substrate height and are configured to modulate a phase of incident light. The nanostructures are respectively arranged at the respective positions for phase design, such that the designed metasurface having the stepped substrate can achieve the same function of the metasurface having the curved substrate, at the same time, be thinner than the metasurface having the curved substrate. Respective positions for phase design are planes with different substrate heights. Thus, unlike the metasurface having the curved substrate which must be processed by a complex processing technology, the metasurface with the stepped substrate is processed simply by the existing semiconductor planar processing technology, in other words, the processing of the metasurface with the stepped substrate is much simpler than the processing of the metasurface with the curved substrate, thus, it is easier to implement the mass production and the promotion of the metasurface with the stepped substrate.

### Embodiment 2

FIG. 5 shows a flow chart of a method of processing a metasurface having a stepped substrate. The method of processing the metasurface having the stepped substrate as provided in the present embodiment is used to process the metasurface having the stepped substrate as provided in the Embodiment 1. The method includes the following steps.

Step 500: performing grayscale lithography on a planar substrate to obtain the stepped substrate.

Step 502: depositing a structural layer on the stepped substrate, where a ratio of a first structural layer thickness to a second structural layer thickness is less than 1/5 in a process of depositing the structural layer, where the first structural layer thickness refers to a thickness of the structural layer along sidewalls of the stepped substrate, and the second structural layer thickness refers to a thickness of the structural layer at a bottom of the stepped substrate.

In the above step 502, the structural layer is deposited on the stepped substrate. Where the ratio of the first structural layer thickness to the second structural layer thickness is less than 1/5 in the process of depositing the structural layer. By such a deposition manner, the structural layer is deposited at respective positions for phase design rather than depositing the structural layer on the sidewalls of the stepped substrate. Consequently, the structural layer is obtained by a simple process.

Where, the manner of depositing the structural layer may be, but is not limited to, electron-beam physical vapor deposition or chemical vapor deposition (such as plasma enhanced chemical vapor deposition, i.e., PECVD).

Optionally, after a step of depositing the structural layer, the method further includes the following step:
depositing a hardmask layer on the structural layer, where a ratio of a first hardmask layer thickness to a second hardmask layer thickness is less than 1/5 in a process of depositing the hardmask layer, where the first hardmask layer thickness refers to a thickness of the hardmask layer along the sidewalls of the stepped substrate, and a second hardmask layer thickness refers to a thickness of the hardmask layer at the bottom of the stepped substrate.

Step 504: coating a photoresist layer on the structural layer.

In the above step 504, a photoresist is sprayed on the structural layer by a nozzle to coat the photoresist layer on the structural layer, such that the photoresist is evenly coated on the structural layer.

In an embodiment, after a step of depositing the hardmask layer on the structural layer, a photoresist is sprayed on the hardmask layer by a nozzle to coat the photoresist layer on the hardmask layer.

The traditional spin-coating hardly applies an even glue layer on a stepped substrate that is discretized. In the present embodiment, the photoresist layer is formed by spaying the photoresist with the nozzle in step 504. In the present embodiment, each position for phase design in the discretized stepped substrate is flat and there is a small difference (a few micrometers) among the substrate heights of the respective positions for phase design, hence, when spraying the photoresist by the nozzle, there is no need to precisely control the height of the nozzle to be consistent with the substrate heights of respective positions for phase design, and there is also no need to rotate the nozzle to adjust the spraying angle, in other words, it is only needed to keep the nozzle vertically downward to spray the photoresist on the whole substrate.

Step 506: exposing and developing the photoresist layer to form a relief sculpture on the stepped substrate.

Step 508: performing etching and removing remaining photoresists, so as to form the nanostructures and obtain the metasurface having the stepped substrate.

Summarily, in the method of processing the metasurface having the stepped substrate as provided in the present embodiment, respective positions for phase design are planes with different substrate heights. Thus, unlike the metasurface having the curved substrate which must be processed by a complex processing technology, the metasurface with the stepped substrate can be processed simply by the existing semiconductor planar processing technology, in other words, the processing of the metasurface with the stepped substrate is much simpler than the processing of the metasurface with the curved substrate, thus, it is easier to implement the mass production and the promotion of the metasurface with the stepped substrate.

### Embodiment 3

The method of designing a metasurface having a stepped substrate as provided in the present embodiment is executed by a server.

The server may be any existing computing device that is capable of executing the method of designing the metasurface having the stepped substrate, and specific details will not be elaborated herein.

The following steps may be required before performing the method of designing the metasurface having the stepped substrate as provided in the present embodiment.

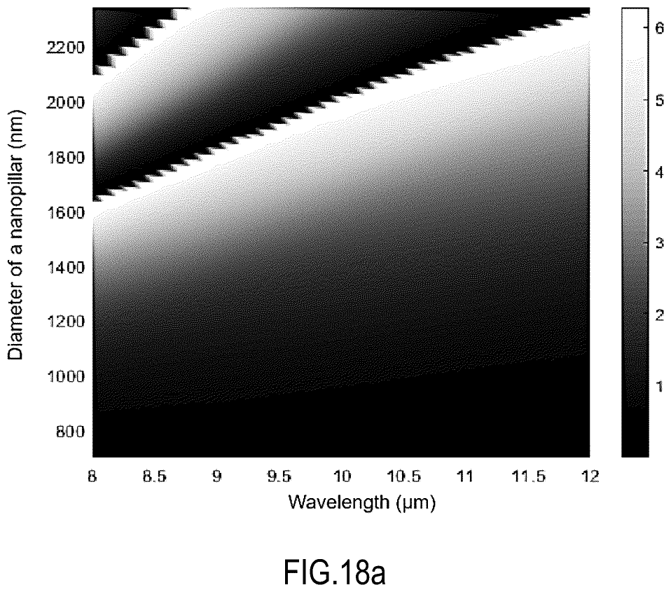

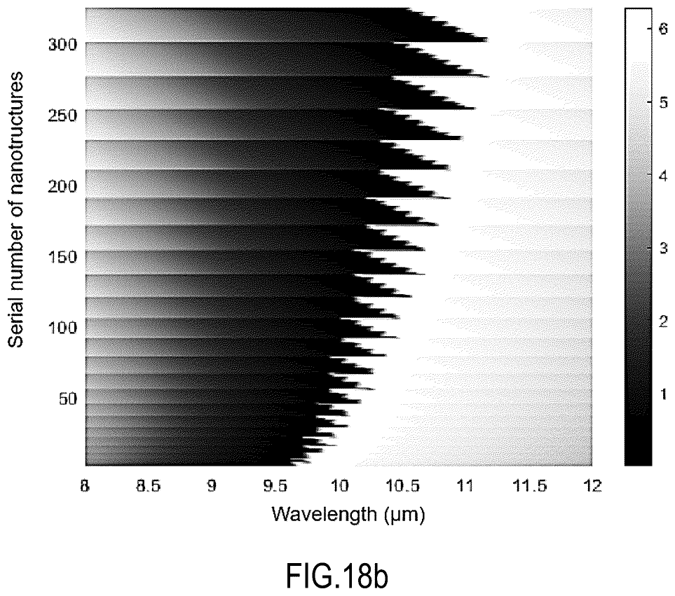

Firstly, a material of the stepped substrate and a material of the nanostructures are determined. Secondly, an operating wavelength range of the metasurface which is configured to generate a target optical lens is determined, and thus, a minimum wavelength λₘᵢₙ and a maximum wavelength λₘₐₓ of the operating wavelength range are determined. Based on the minimum wavelength λₘᵢₙ and the maximum wavelength λₘₐₓ, a period of nanostructures in a nanostructure database is determined which is greater than or equal to 0.5λₘᵢₙ and less than or equal to 1.5λₘₐₓ, and heights of nanostructures in a nanostructure database are determined which are greater than or equal to 0.1λₘᵢₙ and less than or equal to 10λₘₐₓ. That is, the period P=[0.5λₘᵢₙ, 1.5λₘₐₓ], and the heights H=[0.1λₘᵢₙ, 10λₘₐₓ]. When the achievable process matches with a minimum processable size (known as critical dimension, CD) and the period of the nanostructures is determined which is equal to P0, i.e., P=P0 (where, the value of P0 ranges from 0.5λₘᵢₙ to 1.5λₘₐₓ, i.e., [0.5λₘᵢₙ, 1.5λₘₐₓ]), the nanostructures vary in size within a range, that is, Var_D=[CD, P0-CD]. The phase (λ) and the transmittance (T) of nanostructures under different wavelengths and under the period P and the height H are obtained by scanning parameters of the nanostructures such as the period P and the height H. By exhaustively scanning the period P, the height H and Var_D and setting the number of scanning steps for the period and the nanostructure variation to be greater than or equal to 10, a nanostructure database is established. Referring to FIG. 18a and FIG. 18b, a nanostructure database is schematically shown. The nanostructure database records information such as the period (P), the structural type, the material, the height, the transmittance, the phase of respective nanostructures.

Where, the structural type refers that a nanostructure may be, but is not limited to, a nanopillar, for example, being a square nanopillar or an annular nanopillar. The annular nanopillar may have a square shape.

When the operating wavelength range is a visible spectrum, a material of the nanostructures may be, but is not limited to, silicon nitride, titanium oxide, gallium nitride, gallium phosphide, hydrogenated amorphous silicon, sapphire or silicon oxide.

When the operating wavelength range is a far-infrared band (8-12 μm), a material of the nanostructures may be, but is not limited to, crystalline silicon or crystalline germanium.

For example, a material of the nanostructures is silicon; a material of the stepped substrate is silicon; a period P of the nanostructures is equal to 3 μm; a height H of the nanostructures is equal to 10 μm; the metasurface is a converging lens without chromatic aberration and spherical aberration with a diameter ranging from 0.5 μm to 2.5 μm. A main wavelength of 10 μm is selected; and a material of the substrate is silicon. In the selected nanostructure database, a material of the nanostructures is silicon; a material of the stepped substrate is silicon; a period P of the nanostructures is equal to 3 μm; a height H of the nanostructures is equal to 10 μm; respective nanostructures may be a circular nanopillar, a circular nanohole, an annular nanopillar or an annular nanohole. Phases in respective nanostructure database are shown in the accompanying phase diagrams.

When the operating wavelength range is a visible spectrum, the stepped substrate is transparent to visible light, and a material of the substrate may be, but is not limited to, fused quartz, crown glass, flint glass, or sapphire.

When the operating wavelength range is a far-infrared band (8-12 μm), a material of the substrate may be, but is not limited to, chalcogenide glass, zinc sulfide, zinc selenide, crystalline germanium or crystalline silicon.

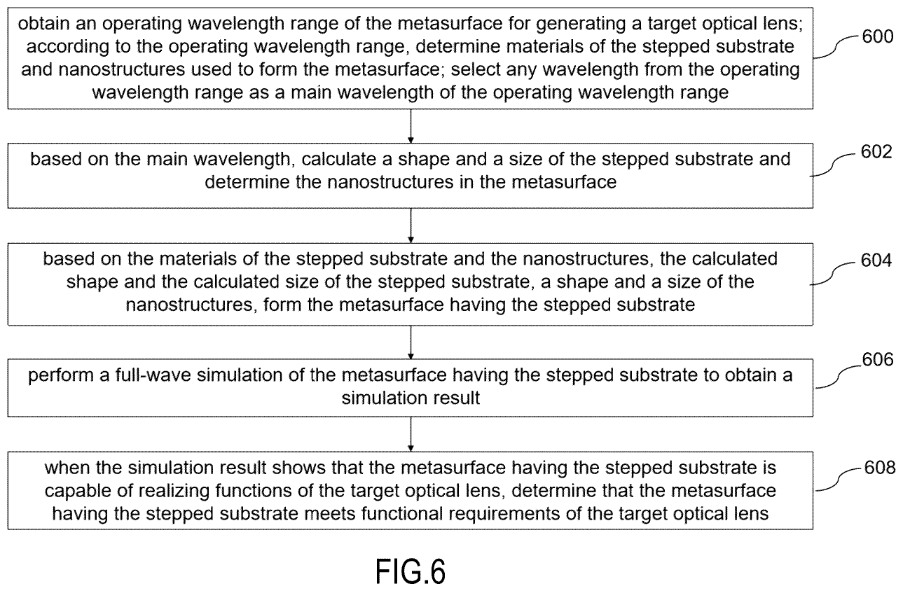

The method of designing the metasurface having the stepped substrate may be performed after establishing the nanostructure database. FIG. 6 shows a flow chart of the method of designing the metasurface having the stepped substrate. The method of designing the metasurface having the stepped substrate as provided in the present embodiment includes the following steps.

Step 600: obtaining an operating wavelength range of the metasurface which is configured to generate a target optical lens; according to the operating wavelength range, determining a material of the stepped substrate and a material of nanostructures, where the stepped substrate and the nanostructures form the metasurface; and selecting any wavelength from the operating wavelength range as a main wavelength of the operating wavelength range.

In the above step 600, pre-stored in the server are a first corresponding relationship between the operating wavelength range and a material of the nanostructures, and a second corresponding relationship between the operating wavelength range and a material of the substrate. Thus, materials of the stepped substrate and the nanostructures that form the metasurface are determined according to the operating wavelength range, and the first corresponding relationship and the second corresponding relationship.

When the metasurface having the stepped substrate to be designed serves as a converging lens designed to operate in the far infrared spectrum (8 μm-12 μm), the server may choose any wavelength (such as 10 μm) from the range of 8 μm-12 μm as the main wavelength.

For the target optical lens that is generated based on the metasurface having the stepped substrate, stored in the server are parameters such as the focal length and the refractive index of the target optical lens.

In addition to the foregoing parameters, further stored in the server are the refractive indices of substrates of different materials for light with different wavelengths.

Where, the refractive indices of the substrates of different materials for the light with different wavelengths may be expressed by a corresponding relationship between a material of the substrate, a light wavelength range and the refractive indices.

Step 602: based on the main wavelength, calculating a shape and a size of the stepped substrate and determining the nanostructures in the metasurface.

In an embodiment, a step of “based on the main wavelength, calculating the shape and the size of the stepped substrate” in the step 602 includes the following steps of (1)-(4).

Step (1): calculating a required phase for modulating light with the main wavelength.

Step (2): according to the required phase for modulating the light with the main wavelength, calculating first phases which refer to phases of respective positions for phase design in the stepped substrate required for allowing the light with the main wavelength to transmit through the respective positions for phase design.

Step (3): obtaining the refractive index of the stepped substrate for the light with the main wavelength; calculating substrate heights of the respective positions for phase design according to the refractive index of the stepped substrate for the light with the main wavelength, the first phases, and the main wavelength of the operating wavelength range, where substrate heights of adjacent positions for phase design are different, thereby forming the metasurface having the stepped substrate.

Step (4): obtaining other wavelengths of the operating wavelength range, and obtaining refractive indices of the stepped substrate for light with the other wavelengths of the operating wavelength range; based on parameters, calculating second phases which refer to phases of the respective positions required for allowing the light with the other wavelengths of the operating wavelength range to transmit through the respective positions for phase design, where the parameters include the other wavelengths of the operating wavelength range, the refractive indices of the stepped substrate for the light with the other wavelengths of the operating wavelength range, and the substrate heights of the respective positions for phase design.

In an embodiment, a step of “calculating the required phase for modulating light with the main wavelength” in the above step (1) includes the following steps of (11)-(12).

Step (11): obtaining a focal length of the target optical lens generated based on the metasurface having the stepped substrate.

Step (12): calculating the required phase for modulating light with the main wavelength according to the main wavelength of the operating wavelength range and the focal length of the target optical lens generated based on the metasurface having the stepped substrate.

The required phase for modulating light with the main wavelength is calculated by a following formula:

$$\\ {ϕ}_{design} ( x , y ) = \frac{2 π}{{λ}_{c}} ( f - \sqrt{{x}^{{}_{} 2} + {y}^{{}_{} 2} + {f}^{{}_{} 2}} )$$

where, f represents the focal length of the target optical lens; λ_{c} represents the main wavelength of the operating wavelength range.

Optionally, the required phase for modulating light with the main wavelength may be calculated by any other existing phase calculation method, which will not be elaborated herein.

A following formula may be used to calculate the first phases as recited in the step (2):

$$\\ {ϕ}_{c} ( x , y ) = mod ( {ϕ}_{design} ( x , y ) , 2 π )$$

where, ϕ_{c}(x, y) represents the first phases.

In order to obtain the refractive index of the stepped substrate for the light with the main wavelength as recited in the step (3), a server may be used. Based on the determined material of the substrate and the determined main wavelength, and by iterating over refractive indices of substrates of different materials for light with different wavelengths stored in the server, the refractive index of the stepped substrate for the light with the main wavelength is obtained.

After obtaining the refractive index of the stepped substrate for the light with the main wavelength, the substrate heights of the respective positions for phase design are calculated by the server according to the following formula:

$$\\ h ( x , y ) = \frac{{λ}_{c} {ϕ}_{c} ( x , y )}{2 π ( {n}_{c} - 1 )}$$

where, h(x, y) represents the substrate heights of the respective positions for phase design; ϕ_{c}(x, y) represents the first phases; n_{c} represents the refractive index of the stepped substrate for the light with the main wavelength.

The other wavelengths of the operating wavelength range as recited in the step (4) refer to the remaining wavelengths within the operating wavelength range excluding the selected main wavelength.

Refractive indices of the stepped substrate for light with the other wavelengths of the operating wavelength range are obtained by firstly obtaining the material of the substrate, and then iterating over refractive indices of substrates of different materials for light with different wavelengths stored in the server according to the material of the substrate and the other wavelengths of the operating wavelength range.

The second phases are calculated by the server according to the following formula:

$$\\ {ϕ}_{substrate} ( x , y , λ ) = \frac{2 π}{λ} ( n ( λ ) - 1 ) h ( x , y )$$

where, h(x, y) represents the substrate heights of the respective positions for phase design; n(λ) represents the refractive indices of the stepped substrate for light with the other wavelengths of the operating wavelength range; λ represents the other wavelengths in the operating wavelength range; ϕ_{substrate}(x, y, λ) represents the second phases.

The following steps of (41)-(42) may be performed after calculating the shape and the size of the stepped substrate based on the obtained main wavelength. In addition, the nanostructures in the metasurface are determined based on the obtained main wavelength.

Step (41): obtaining a designed phase of the metasurface for correcting chromatic aberration; calculating a required phase of the nanostructures according to the second phases and the designed phase.

Step (42): performing an inquiry within a nanostructure database to obtain a target nanostructure with a phase closest to the required phase of the nanostructures, where a nanostructure-phase relationship is stored in the nanostructure database.

The designed phase of the metasurface for correcting chromatic aberration obtained in the step (41) corresponds to functions of the target optical lens to be designed.

In the server, a corresponding relationship between the designed phase of the metasurface for correcting chromatic aberration and the target optical lens formed based on the metasurface having the stepped substrate is pre-stored.

In an embodiment, the corresponding relationship between the designed phase of the metasurface for correcting chromatic aberration and the target optical lens formed based on the metasurface having the stepped substrate is shown as follows:
a first designed phase of the metasurface for correcting chromatic aberration is associated with an achromatic converging (positive) lens;
a second designed phase of the metasurface for correcting chromatic aberration is associated with an achromatic diverging (negative) lens;
a third designed phase of the metasurface for correcting chromatic aberration is associated with a phase correction plate with a refractive-meta hybrid optical system.

Therefore, the server is capable of obtaining the designed phase of the metasurface for correcting chromatic aberration by the inquiry according to the target optical lens formed based on the metasurface having the stepped substrate.

Optionally, the designed phase of the metasurface for correcting chromatic aberration may be manually fed into the server, so that the server obtains the designed phase of the metasurface for correcting chromatic aberration.

The required phase of the nanostructures is calculated according to the following formula:

$$\\ {ϕ}_{total} ( x , y , λ ) = mod ( {ϕ}_{substrate} ( x , y , λ ) + {ϕ}_{nanostructure} ( x , y , λ ) , 2 π )$$

where, ϕₜₒₜₐₗ(x, y, λ) represents the designed phase of the metasurface for correcting chromatic aberration; ϕ_{nanostructure}(x, y, λ) represents the required phase of the nanostructures.

The following steps of (421)-(422) are executed to perform the inquiry within the nanostructure database to obtain the target nanostructure with a phase closest to the required phase of the nanostructures.

Step (421): querying phases of predetermined nanostructures in the nanostructure database.

Step (422): calculating differences between the required phase of the nanostructures and respective phases of the predetermined nanostructures, so as to obtain a smallest difference and a nanostructure among the predetermined nanostructures corresponding to the smallest difference; and taking the corresponding nanostructure as the target nanostructure with the phase closest to the required phase of the nanostructures.

In an embodiment, the step of calculating differences between the required phase of the nanostructures and respective phases of the predetermined nanostructures as recited in the step (422) is performed by direct calculation. That is, by subtracting the required phase of the nanostructures from a phase of a predetermined nanostructure, a difference is obtained.

In an embodiment, target nanostructures are found out through an optimization algorithm of minimizing a weighted error. The relevant principle may be expressed by the following formula:

$$\\ min Δ ( x , y ) = {\sum }_{i} {c}_{i} \vert {φ}_{nanostructure} ( x , y , {λ}_{i} ) - {φ}_{j \_ lib} ( x , y , {λ}_{i} ) \vert$$

where, Δ(x, y) represents differences between the required phase of the nanostructures and respective phases of the predetermined nanostructures; ϕ_{nanostructure}(x, y, λᵢ) represents a required phase of the nanostructures under a wavelength λᵢ; φ_{j_lib} (x, y, λᵢ) represents a phase of a j-th predetermined nanostructure in the nanostructure database under the wavelength λᵢ; cᵢ represents a weighting coefficient at the wavelength λᵢ, generally the weighting coefficient is equal to 1.

Step 604: based on materials of the stepped substrate and the nanostructures that form the metasurface, the calculated shape and the calculated size of the stepped substrate, a shape and a size of the nanostructures, forming the metasurface having the stepped substrate.

Step 606: performing a full-wave simulation of the metasurface having the stepped substrate to obtain a simulation result.

Specifically, in the full-wave simulation of the designed metasurface having the stepped substrate, an interval between a maximum wavelength λₘₐₓ and a minimum wavelength λₘᵢₙ is not less than (λₘₐₓ−λₘᵢₙ)/10 for light field propagation, and then all light fields are weighted and superimposed to obtain a full-wave simulation result.

Where, a weighting value used in the weighting and the superimposing is the relative amplitude (i.e., the square root of a light intensity ratio) of the respective wavelengths of the operating wavelength range. Generally, all weighting coefficients are equal to 1. For example, when the metasurface having the stepped substrate is designed to be a converging lens for broad spectrum light, identifying whether light passing through the metasurface focuses at a single point is a judging rule for determining whether such design satisfies the requirements.

Specifically, the light focusing satisfies the demands when the half-width of an optical focal spot along an optical axis of the metasurface is less than or equal to twice the half-width defined by the diffraction limit, that is,

$$\\ {FWHM}_{real} \leq 2 \frac{4 \overline{λ}}{{NA}^{{}_{} 2}} .$$

Where, λ̅ is an average wavelength of light incident on the metasurface; NA is a numerical aperture of an optical system obtained by treating the discretized stepped substrate and nanostructures on the discretized substrate as a whole; FWHMᵣₑₐₗ is the half-width of the optical focal spot along the optical axis of the metasurface.

Step 608: when the simulation result shows that the metasurface having the stepped substrate is capable of realizing functions of the target optical lens, determining that the metasurface having the stepped substrate meets functional requirements of the target optical lens.

Otherwise, returning to the step 600 when the obtained simulation result shows that the metasurface having the stepped substrate fails to realize the functions of the target optical lens to be designed. In this case, selecting other wavelengths in the operating wavelength range as a main wavelength to design the metasurface having the stepped substrate, until the designed metasurface meets functional requirements of the target optical lens.

In an embodiment, the following lens is designed according to the method of designing the metasurface having the stepped substrate as provided in the present embodiment:

1) When it is required to design a metasurface as a converging lens without chromatic aberration and spherical aberration which operates in the far infrared spectrum (8 μm-12 μm) and has a focal length of 15 mm and an aperture of 5 mm, the main wavelength of 10 μm is selected, and the material of the substrate is silicon. In the selected nanostructure database, a material of the nanostructures is silicon; a material of the substrate is silicon; a period P of the nanostructures is equal to 3 μm; a height H of the nanostructures is equal to 10 μm; respective nanostructures may be a circular nanopillar, a circular nanohole, an annular nanopillar or an annular nanohole. Phases in respective nanostructure database are shown in the accompanying phase diagrams.

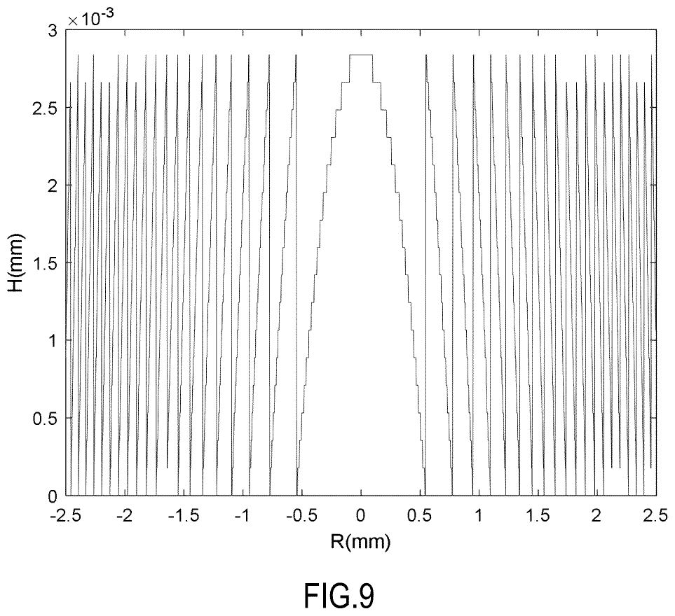

According to the foregoing formula of calculating the substrate heights of the respective positions for phase design, it is achievable to obtain the substrate heights and the corresponding phases of the respective positions at different wavelengths. FIG. 9 shows phases of respective positions for light with different wavelengths as a function of substrate heights.

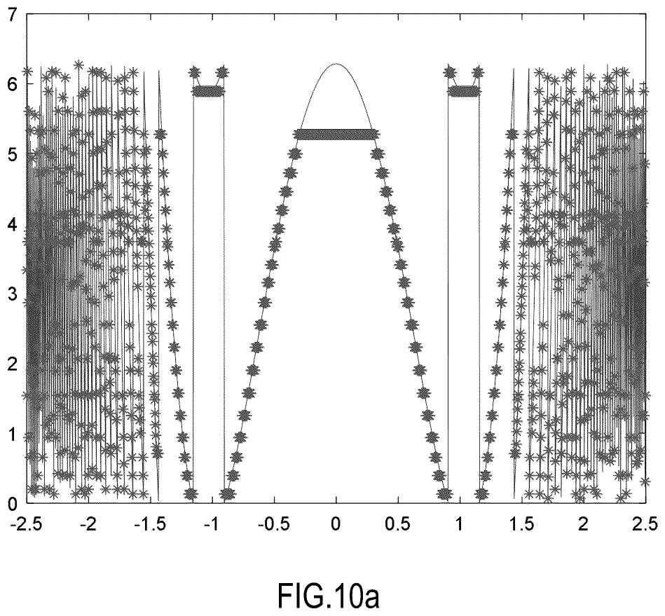

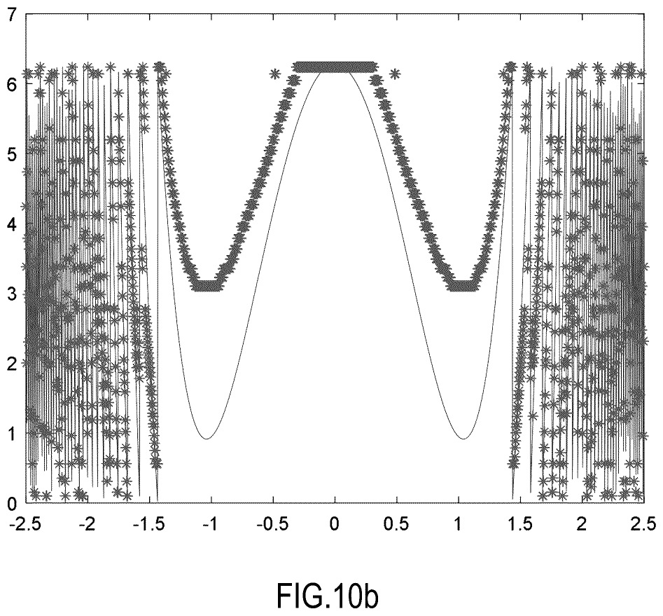

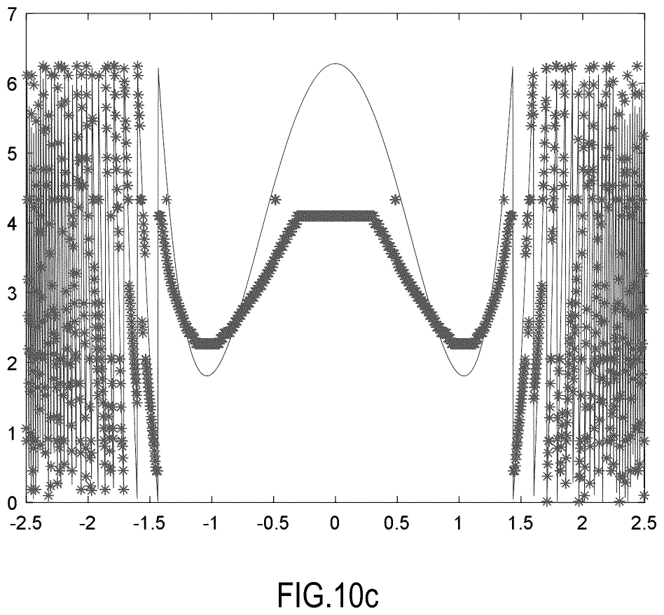

Then, according to the foregoing formula of calculating the required phase of the nanostructures and the optimization algorithm of minimizing the weighted error used in the search of the target nanostructures, the required phase and the actual phase of the nanostructures at respective wavelengths of 8 μm, 10 μm and 12 μm are obtained and shown in FIG. 10a to FIG. 10c.

Results of the full-wave simulation show the light focusing of the metasurface of the present embodiment at a full spectrum range of 8 μm-12 μm (the wavelength spacing is 0.08 μm). In the full-wave simulation diagrams, the half-width of light intensity along the optical axis of the metasurface is less than twice the half-width confined by the diffraction limit, proving that the metasurface has satisfactory light focusing performance.

At the same time, the light focusing of the discretized stepped substrate alone and the light focusing of the nanostructures alone at 8 μm, 10 μm and 12 μm are respectively shown in diagrams, and it is seen from the diagrams that the focusing without chromatic aberration and spherical aberration is achievable by a design idea in which different nanostructures and a substrate with dispersion properties are combined.

2) When it is required to design a metasurface as a diverging lens without chromatic aberration and spherical aberration which operates in the far infrared spectrum (8 μm-12 μm) and has a focal length of −15 mm and an aperture of 5 mm, the main wavelength of 10 μm is selected, and the material of the substrate is silicon. In the selected nanostructure database, a material of the nanostructures is silicon; a material of the substrate is silicon; a period P of the nanostructures is equal to 3 μm; a height H of the nanostructures is equal to 10 μm; respective nanostructures may be a circular nanopillar, a circular nanohole, an annular nanopillar or an annular nanohole. Phases in respective nanostructure database are shown in the accompanying phase diagrams.

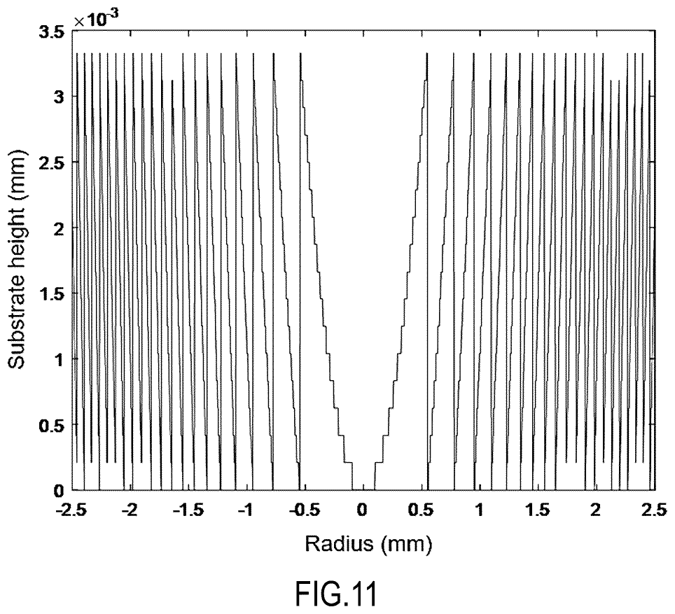

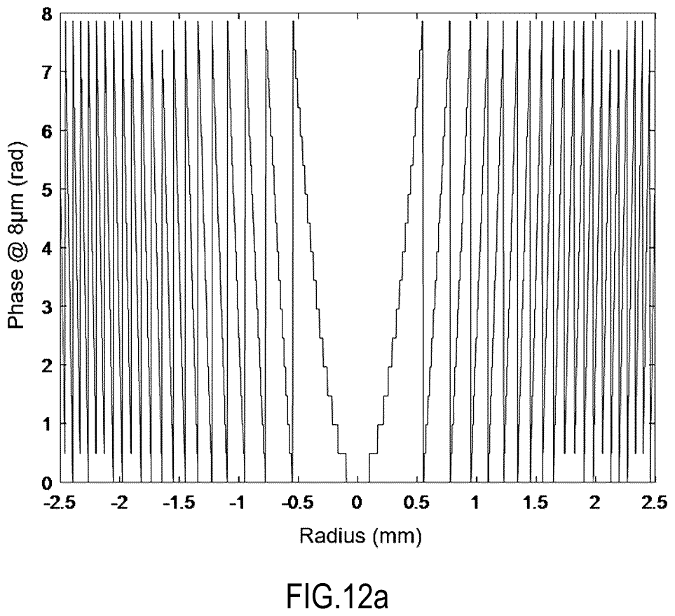

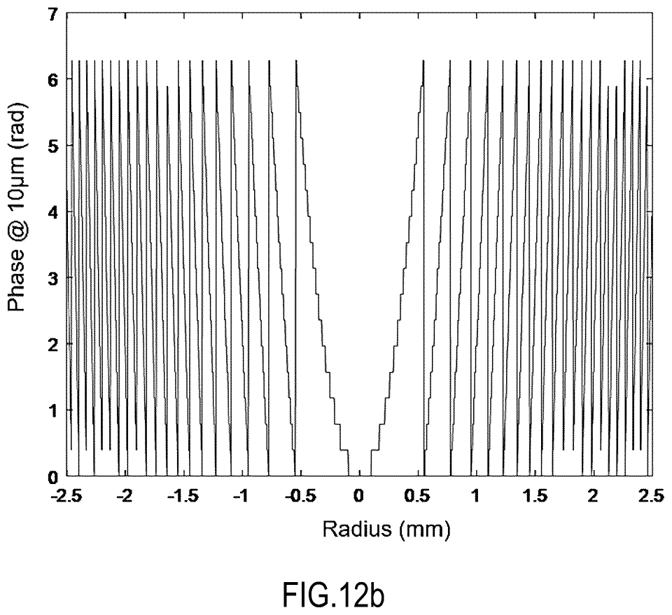

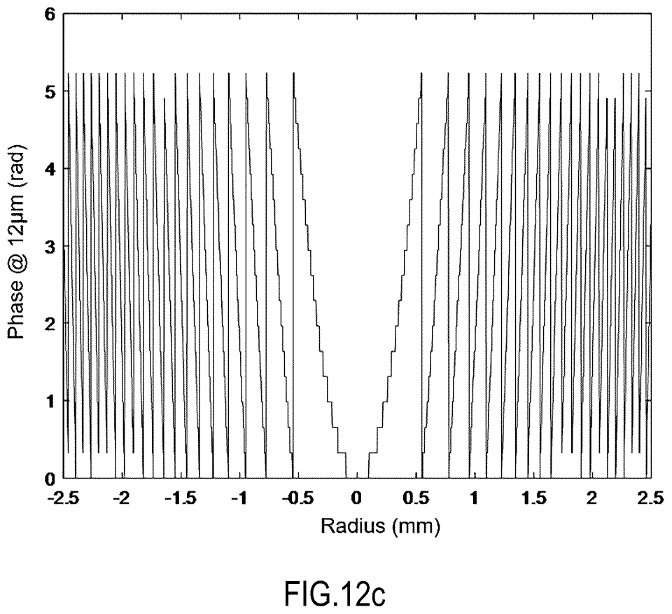

According to the following formulas Eq-1 to Eq-3, the corresponding substrate heights are obtained and are shown in FIG. 11. Chromatic aberration phases corresponding to respective substrate heights at 8 μm, 10 μm and 12 μm are obtained according to the following formula Eq-4. The obtained chromatic aberration phases are shown in FIG. 12a to FIG. 12c.

The shapes of the substrate (x, y, h) are calculated based on the required phase ϕ_{design} of modulating light with the main wavelength of the operating wavelength range. The required phase ϕ_{c} of a point (x,y) on the substrate for light with a central wavelength λ_{c} is calculated according to the following formula Eq-1:

$$\\ {ϕ}_{c} ( x , y ) = mod ( {ϕ}_{design} ( x , y ) , 2 π )$$

When it is required to design a converging lens (with a focal length f), a phase of the designed converging lens is calculated according to the following formula Eq-2:

$$\\ {ϕ}_{design} ( x , y ) = \frac{2 π}{{λ}_{c}} ( f + \sqrt{{x}^{{}_{} 2} + {y}^{{}_{} 2} + {f}^{{}_{} 2}} )$$

where, mod(, 2π) is a modulo 2π function for a specific value. The substrate height h(x, y) at the position (x, y) is determined according to the first phases ϕ_{c}(x, y) and the following formula Eq-3:

$$\\ h ( x , y ) = \frac{{λ}_{c} {ϕ}_{c} ( x , y )}{2 π ( {n}_{c} - 1 )}$$

where, n_{c} is the refractive index of the material of the stepped substrate for light with the main wavelength. According to the substrate height h(x, y), a phase of the stepped substrate for modulating light with other wavelengths λ is calculated according to the following formula Eq-4:

$$\\ {ϕ}_{substrate} ( x , y , λ ) = \frac{2 π}{λ} ( n ( λ ) - 1 ) h ( x , y )$$

where, n(λ) is the refractive index of the material of the stepped substrate for light with the wavelength λ.

In order to realize chromatic aberration correction for light with wavelengths of 8 μm-12 μm, the phase of the nanostructures needs to satisfy the above formula for calculating the required phase of the nanostructures. Furthermore, according to the above formula for calculating the required phase of the nanostructures, it is achievable to obtain all nanostructures at different positions for phase design in the stepped substrate, where the stepped substrate can be regarded as a plurality of discretized planar lenses with a negative focal length and unequal height. Phase discretization is attainable according to the foregoing optimization algorithm of minimizing the weighted error used in the search of the target nanostructures.

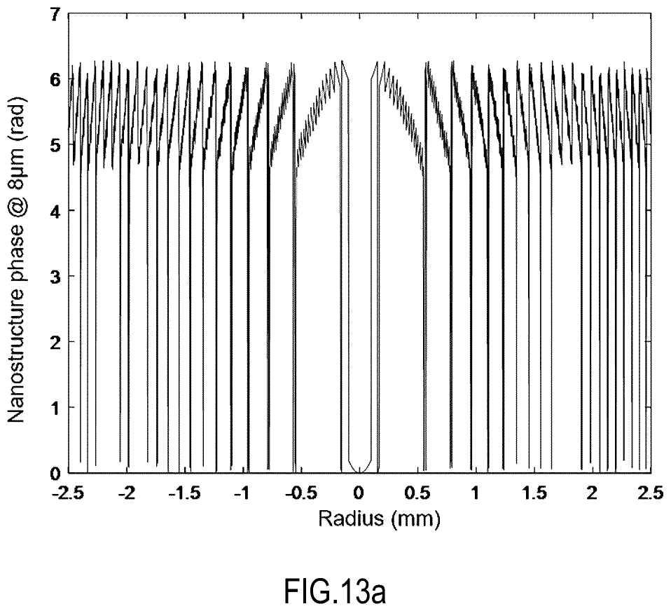

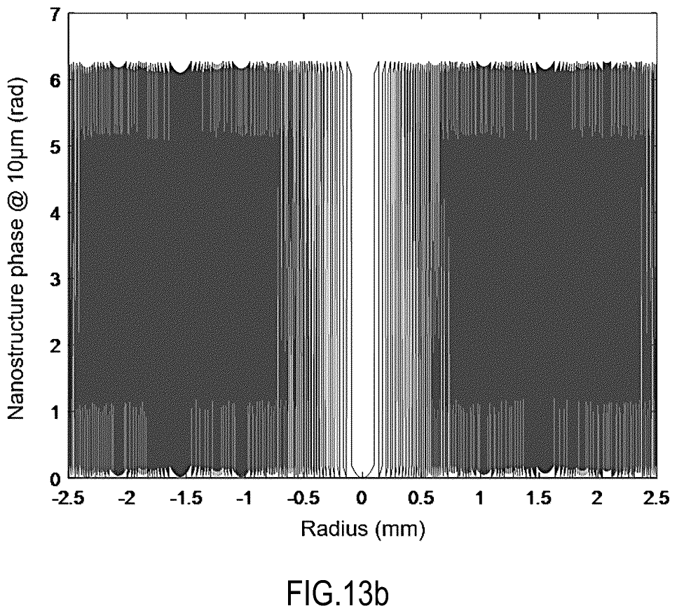

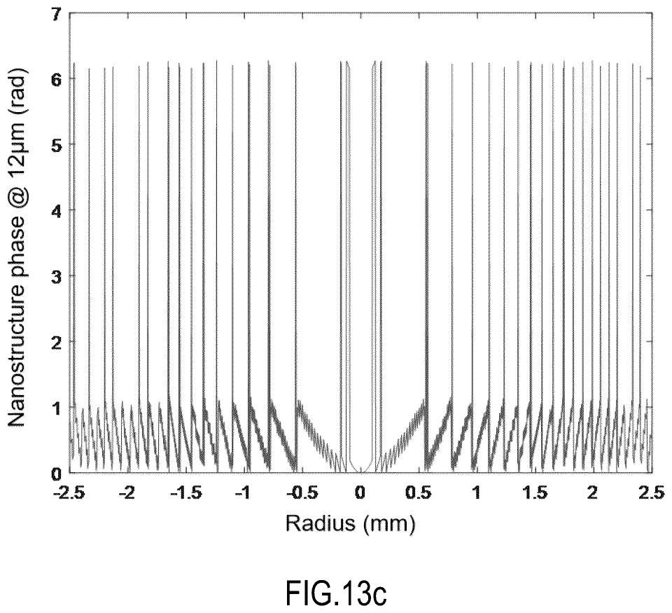

FIG. 13a to FIG. 13c respectively show the required phase of the nanostructures for light with three different main wavelengths of 8 μm, 10 μm and 12 μm.

3) A phase correction plate formed by a refractive-meta hybrid optical system

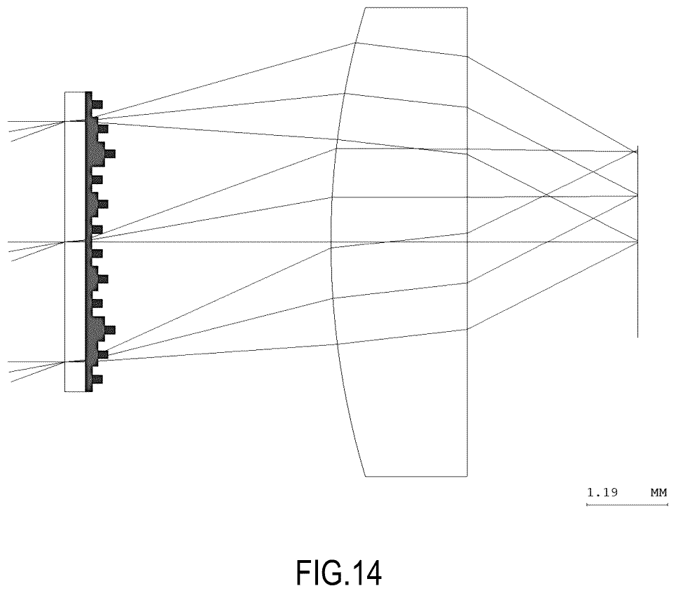

The phase correction plate includes a metalens and a germanium refractive lens. The phase correction plate operates at a wavelength band of 8 μm-12 μm, and has a field of view of 40°, an F number of 1.1, and a back focal length of 3 mm. The refractive-meta hybrid optical system is schematically shown in FIG. 14. Where, the metalens is arranged on a left side of the refractive-meta hybrid optical system as shown in FIG. 14, and the refractive lens is arranged on a right side of the refractive-meta hybrid optical system as shown in FIG. 14. The phase of the stepped substrate of the phase correction plate is calculated according to the following formula Eq-5 (where the main wavelength is expressed as λ_{c}):

$$\\ {φ}_{corrector \_ sub} ( r ) = \frac{2 π}{{λ}_{c}} ( {a}_{1} {r}^{{}_{} 2} + {a}_{2} {r}^{{}_{} 4} + {a}_{3} {r}^{{}_{} 6} )$$

where, a₁, a₂ and a₃ represent optimization coefficients respectively; r represents a distance from a point on the phase correction plate to a center of the phase correction plate along a radial direction of the phase correction plate.

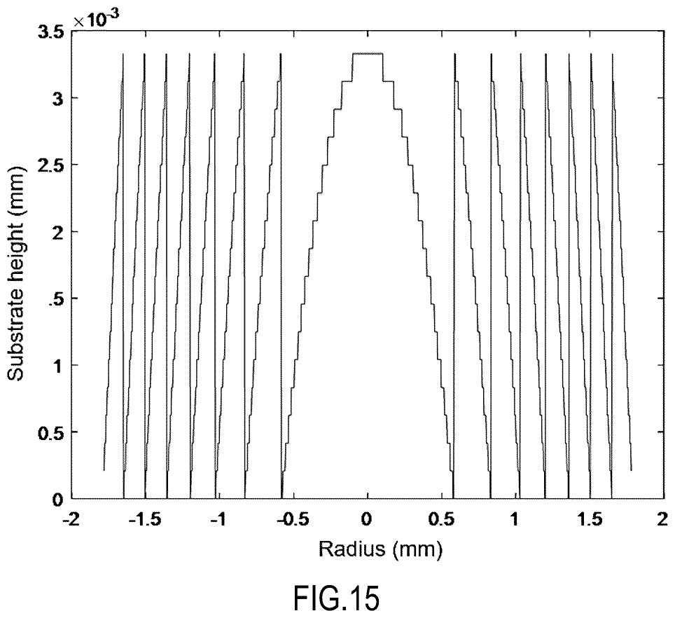

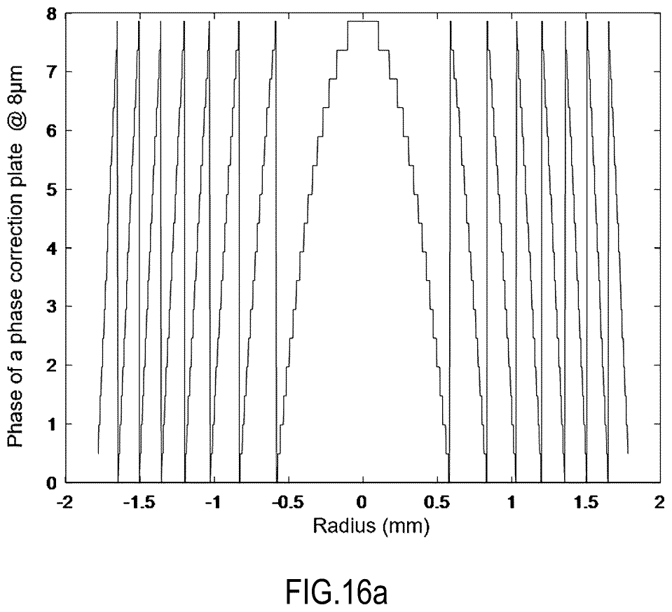

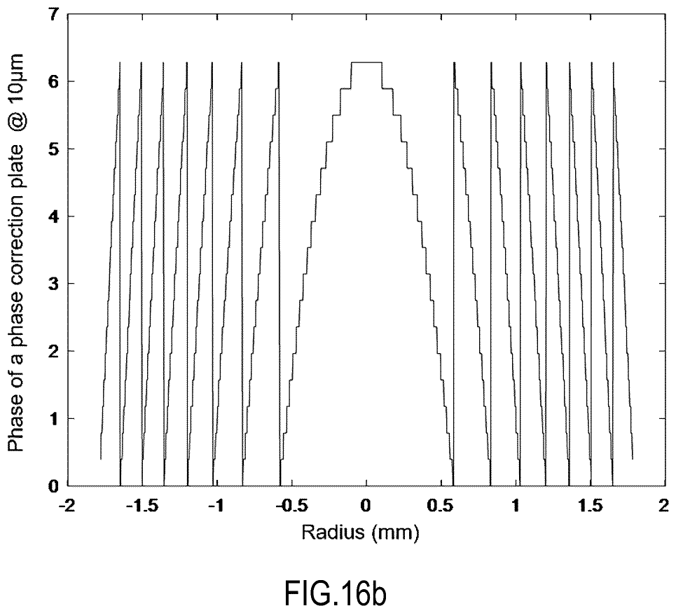

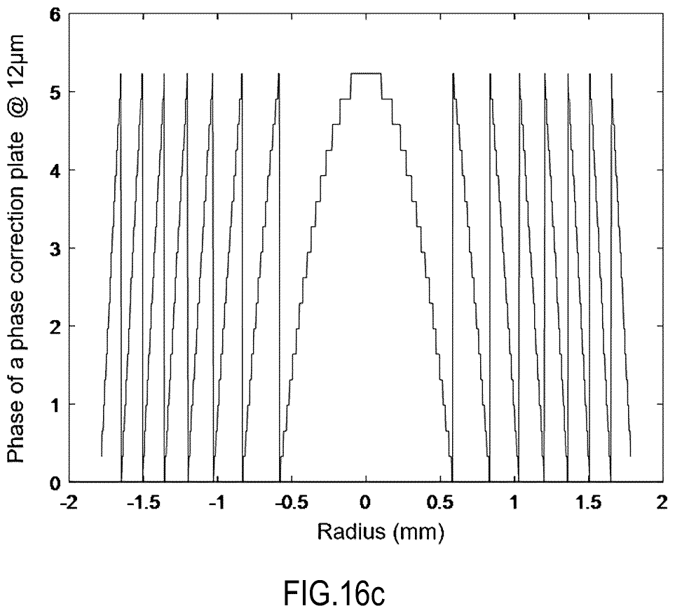

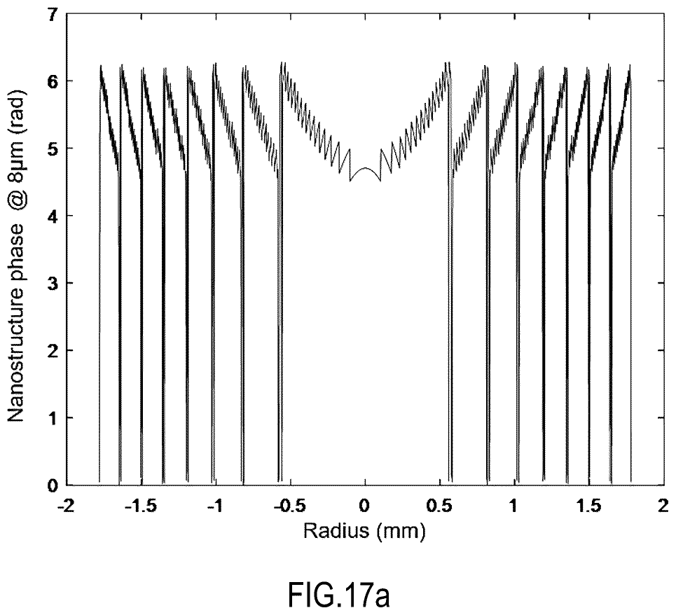

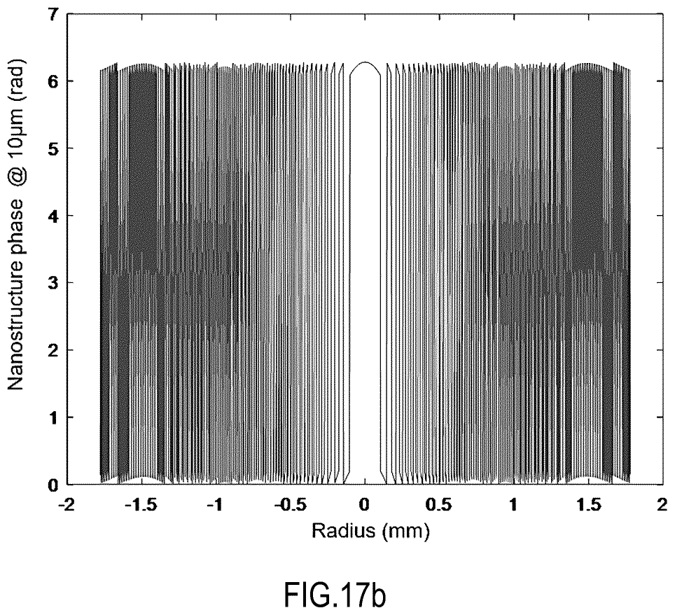

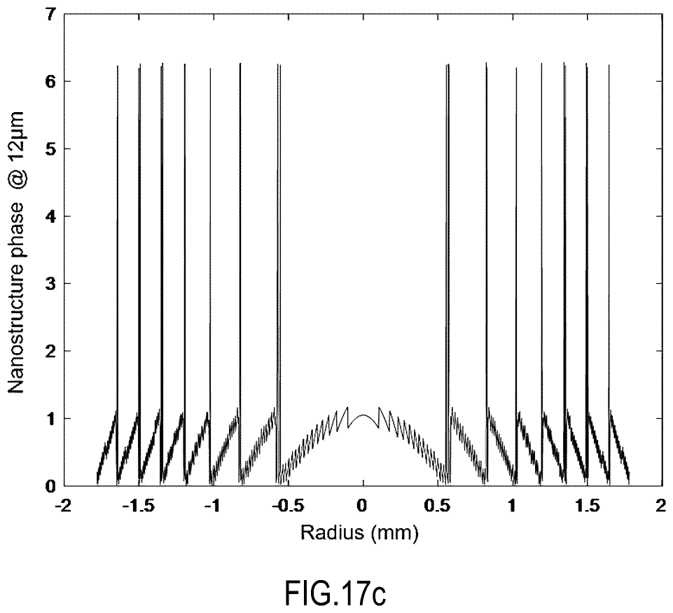

According to the foregoing formulas Eq-1, Eq-3, Eq-4, and the foregoing formula of calculating the required phase of the nanostructures, substrate heights of the phase correction plate are obtained and shown in FIG. 15. Dispersion phases are shown in FIG. 16a to FIG. 16c. According to the optimization algorithm of minimizing the weighted error used in the search of the target nanostructures, it is achievable to obtain theoretical phases of the nanostructures at 8 μm, 10 μm and 12 μm, as shown in FIG. 17a to FIG. 17c.

In summary, the present embodiment provides a method of designing a metasurface having a stepped substrate. The method includes obtaining an operating wavelength range of the metasurface which is configured to generate a target optical lens; according to the operating wavelength range, determining a material of the stepped substrate and a material of nanostructures, where the stepped substrate and the nanostructures form the metasurface; selecting any wavelength from the operating wavelength range as a main wavelength of the operating wavelength range; based on the main wavelength, obtaining a shape and a size of the stepped substrate and determining the nanostructures in the metasurface; based on the material of the stepped substrate and the material of the nanostructures, the calculated shape and the calculated size of the stepped substrate, a shape and a size of the nanostructures, forming the metasurface having the stepped substrate; performing a full-wave simulation of the metasurface having the stepped substrate to obtain a simulation result; when the simulation result shows that the metasurface having the stepped substrate is capable of realizing functions of the target optical lens, determining that the metasurface having the stepped substrate meets functional requirements of the target optical lens. Whereby, a metasurface having a stepped substrate that is capable of realizing the target functions is obtainable according to the functional requirements of the target optical lens. In addition, the metasurface having the stepped substrate can be approximately assumed as including a plurality of planar substrate, and thus it is feasible to process the metasurface of the present embodiment by the existing semiconductor planar processing technology, being suitable for mass production.

### Embodiment 4

The present embodiment provides a device for designing a metasurface having a stepped substrate, configured to execute the method of designing the metasurface having the stepped substrate as provided in Embodiment 3.

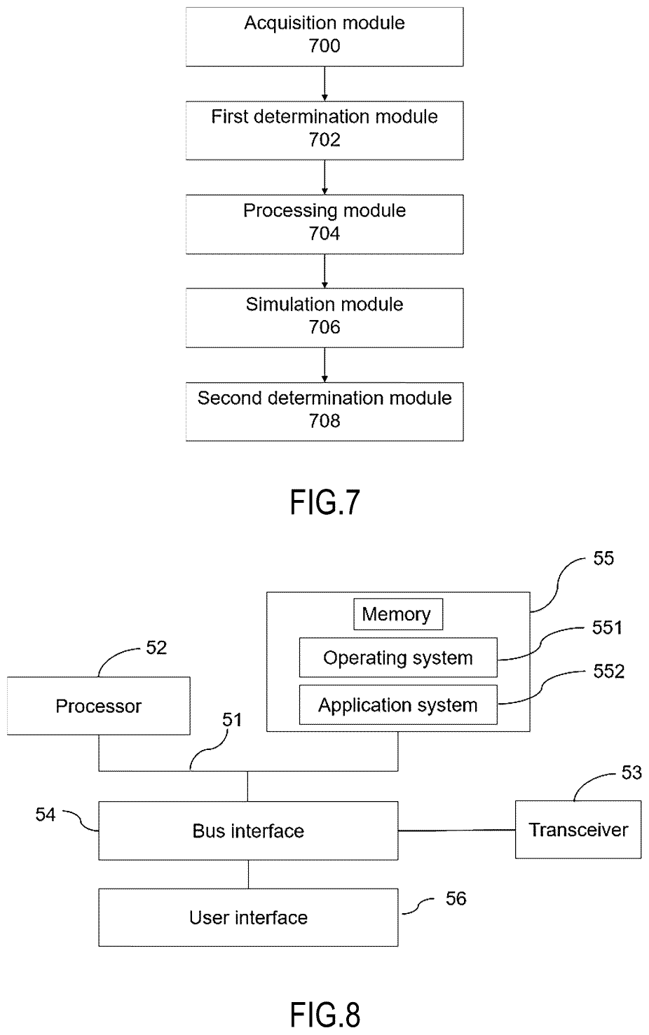

Provided in the present embodiment is a device for designing a metasurface having a stepped substrate, as shown in FIG. 7. The device includes:
an acquisition module 700, configured to obtain an operating wavelength range of the metasurface which is configured to generate a target optical lens; and configured to determine materials of the stepped substrate and nanostructures used to form the metasurface according to the operating wavelength range; and configured to select any wavelength from the operating wavelength range as a main wavelength of the operating wavelength range;
a first determination module 702, configured to calculate a shape and a size of the stepped substrate and determine the nanostructures in the metasurface based on the main wavelength;
a processing module 704, configured to form the metasurface having the stepped substrate based on the material of the stepped substrate and the material of the nanostructures, the calculated shape and the calculated size of the stepped substrate, a shape and a size of the nanostructures;
a simulation module 706, configured to perform a full-wave simulation of the metasurface having the stepped substrate to obtain a simulation result;
a second determination module 708, configured to determine that the metasurface having the stepped substrate meets functional requirements of the target optical lens when the simulation result shows that the metasurface having the stepped substrate is capable of realizing functions of the target optical lens.

In summary, the present embodiment provides a device for designing a metasurface having a stepped substrate. The device is configured to execute steps of obtaining an operating wavelength range of the metasurface which is configured to generate a target optical lens; according to the operating wavelength range, determining a material of the stepped substrate and a material of nanostructures, where the stepped substrate and the nanostructures form the metasurface; selecting any wavelength from the operating wavelength range as a main wavelength of the operating wavelength range; based on the main wavelength, obtaining a shape and a size of the stepped substrate and determining the nanostructures in the metasurface; based on the material of the stepped substrate and the material of the nanostructures, the calculated shape and the calculated size of the stepped substrate, a shape and a size of the nanostructures, forming the metasurface having the stepped substrate; performing a full-wave simulation of the metasurface having the stepped substrate to obtain a simulation result; when the simulation result shows that the metasurface having the stepped substrate is capable of realizing functions of the target optical lens, determining that the metasurface having the stepped substrate meets functional requirements of the target optical lens. Whereby, a metasurface having a stepped substrate that is capable of realizing the target functions is obtainable according to the functional requirements of the target optical lens. In addition, the metasurface having the stepped substrate can be approximately assumed as including a plurality of planar substrate, and thus it is feasible to process the metasurface of the present embodiment by the existing semiconductor planar processing technology, being suitable for mass production.

### Embodiment 5

The present embodiment provides a non-transitory computer-readable storage medium in which a computer program is stored. The computer program is executed by a processor, so as to implement the method of designing the metasurface having the stepped substrate as described in Embodiment 3. The specific implementation has been discussed in Embodiment 1, and thus will not be repeated herein.

In addition, FIG. 8 schematically shows an electronic device. The electronic device as provided in the present embodiment includes a bus 51, a processor 52, a transceiver 53, a bus interface 54, a memory 55 and a user interface 56. The electronic device also includes a memory 55.

In the present embodiment, the electronic device further includes at least one program stored in the memory 55 and executable on the processor 52. Whereby, the processor executes the at least one program to perform the following steps of (1)-(5).

Step (1): obtaining an operating wavelength range of the metasurface which is configured to generate a target optical lens; according to the operating wavelength range, determining a material of the stepped substrate and a material of nanostructures, where the stepped substrate and the nanostructures form the metasurface; selecting any wavelength from the operating wavelength range as a main wavelength of the operating wavelength range.

Step (2): based on the main wavelength, calculating a shape and a size of the stepped substrate and determining the nanostructures in the metasurface.

Step (3): based on the material of the stepped substrate and the material of the nanostructures, the calculated shape and the calculated size of the stepped substrate, a shape and a size of the nanostructures, forming the metasurface having the stepped substrate.

Step (4): performing a full-wave simulation of the metasurface having the stepped substrate to obtain a simulation result.

Step (5): when the simulation result shows that the metasurface having the stepped substrate is capable of realizing functions of the target optical lens, determining that the metasurface having the stepped substrate meets functional requirements of the target optical lens.

The transceiver 53 is configured to receive and transmit data under the control of the processor 52.

In the present embodiment, the bus 51 represents a bus framework. The bus 51 may include any number of interconnected buses and bridges. The bus 51 is configured to connect various circuits of a memory 55 represented by the memory 55 and at least one processor represented by the processor 52. The bus 51 may also realize the circuit connection of devices such as peripheral equipment, a voltage regulator or power management circuit, which is well known in the art and will not be further described in the present embodiment. The bus interface 54 provides an interface between the bus 51 and the transceiver 53. The transceiver 53 may be an element or may be multiple elements, such as multiple receivers and multiple transmitters, and is configured to provide a unit for communicating with various other devices over a transmission medium. For example, the transceiver 53 receives external data from other devices. The transceiver 53 is used to send the processed data by the processor 52 to other devices. Depending on the type of the computer system, a user interface 56 may also be provided. The user interface 56 may be a touch screen, a physical keyboard, a monitor, a mouse, a speaker, a microphone, a trackball, a joystick or a stylus.

The processor 52 takes charge of the bus 51 and general processing, for example, running a general-purpose operating system as described above. The memory 55 is configured to store data used by processor 52 when performing operations.

Optionally, the processor 52 may be, but is not limited to: a central processing unit, a single chip microcomputer, a microprocessor or a programmable logic device.

It should be understood that the memory 55 in the present embodiment may be a volatile memory, a non-volatile memory, or a combination thereof. Where, the non-volatile memory may be a Read-Only Memory (ROM), a Programmable ROM (PROM), and an Erasable PROM (EPROM), an Electrically EPROM (EEPROM) or a Flash Memory. The volatile memory may be a Random Access Memory (RAM), which is used as an external cache. The RAM may be of various types. For the purpose of illustration but not limitation, the RAM may be a Static RAM (SRAM), a Dynamic RAM (DRAM), a Synchronous DRAM (SDRAM), a Double Data Rate SDRAM (DDRSDRAM), an Enhanced SDRAM (ESDRAM), a synchronous link DRAM (SLDRAM) or a Direct Rambus RAM (DRRAM). The memory 55 described in the present embodiment may be any of memories listed herein or may be any of other appropriate memories, and the present embodiment is not limited thereto.

In the present embodiment, the memory 55 stores the following elements of an operating system 551 and an application program 552, including an executable module and a data structure, a subset of the operating system 551 and the application program 552 or an extended set of the operating system 551 and the application program 552.

Specifically, the operating system 551 includes a variety of system programs including a framework layer, a core library layer and a driver layer, which are used to implement various basic services and process hardware-based tasks. The application program 552 includes a variety of application programs including a Media Player and a Browser, which are used to implement various application services. Programs of implementing the method of the embodiments of the present disclosure may be included in the application program 552.

In summary, the present embodiment provides a computer-readable storage medium and an electronic device, which are configured to execute steps of obtaining an operating wavelength range of the metasurface which is configured to generate a target optical lens; according to the operating wavelength range, determining a material of the stepped substrate and a material of nanostructures, where the stepped substrate and the nanostructures form the metasurface; selecting any wavelength from the operating wavelength range as a main wavelength of the operating wavelength range; based on the main wavelength, obtaining a shape and a size of the stepped substrate and determining the nanostructures in the metasurface; based on the material of the stepped substrate and the material of the nanostructures, the calculated shape and the calculated size of the stepped substrate, a shape and a size of the nanostructures, forming the metasurface having the stepped substrate; performing a full-wave simulation of the metasurface having the stepped substrate to obtain a simulation result; when the simulation result shows that the metasurface having the stepped substrate is capable of realizing functions of the target optical lens, determining that the metasurface having the stepped substrate meets functional requirements of the target optical lens. Whereby, a metasurface having a stepped substrate that is capable of realizing the target functions is obtainable according to the functional requirements of the target optical lens. In addition, the metasurface having the stepped substrate can be approximately assumed as including a plurality of planar substrate, and thus it is feasible to process the metasurface of the present embodiment by the existing semiconductor planar processing technology, being suitable for mass production.

The embodiments of the present disclosure mentioned above are illustrative, and are not intended to limit the present disclosure. The scope of the embodiments of the present disclosure is not limited thereto. All variations, substitutions or improvements based on the spirits and principles of the present disclosure fall within the scope of the present disclosure. Accordingly, the scope of the present application is defined by the appended claims.

What is claimed is:

1. A metasurface having a stepped substrate, comprising: the stepped substrate and nanostructures;
wherein the stepped substrate comprises a plurality of positions for phase design that are configured to modulate a phase of incident light, and substrate heights of two adjacent positions for phase design are different; substrate heights of respective positions for phase design are related to functions of the metasurface; the nanostructures are respectively arranged at the respective positions for phase design.

2. The metasurface having the stepped substrate according to claim 1, further comprising: a filler material;
the metasurface is covered by the filler material to form a top surface that is parallel to a bottom of the metasurface.

3. The metasurface having the stepped substrate according to claim 1, further comprising: a filler material;
the metasurface is covered by the filler material to form a top surface that is parallel to a bottom of the metasurface.

4. The metasurface having the stepped substrate according to claim 3, further comprising: an anti-reflection film or a protective layer;
wherein the anti-reflection film or the protective layer is provided on the top surface of filler material.

5. A method of processing the metasurface having the stepped substrate according to claim 1, the method comprising:
performing grayscale lithography on a planar substrate to obtain the stepped substrate;
depositing a structural layer on the stepped substrate, wherein a ratio of a first structural layer thickness to a second structural layer thickness is less than 1/5 in a process of depositing the structural layer, wherein the first structural layer thickness refers to a thickness of the structural layer along sidewalls of the stepped substrate, and the second structural layer thickness refers to a thickness of the structural layer at a bottom of the stepped substrate;
coating a photoresist layer on the structural layer;
exposing and developing the photoresist layer to form a relief sculpture on the stepped substrate;
performing etching and removing remaining photoresists, so as to form the nanostructures and obtain the metasurface having the stepped substrate.

6. The method according to claim 5, wherein a step of coating the photoresist layer on the structural layer comprises:
performing spray coating by a nozzle to coat the photoresist layer on the structural layer.

7. The method according to claim 5, wherein after a step of “depositing the structural layer on the stepped substrate, wherein the ratio of the first structural layer thickness to the second structural layer thickness is less than 1/5 in the process of depositing the structural layer”, the method further comprises:
depositing a hardmask layer on the structural layer, wherein a ratio of a first hardmask layer thickness to a second hardmask layer thickness is less than 1/5 in a process of depositing the hardmask layer, wherein the first hardmask layer thickness refers to a thickness of the hardmask layer along the sidewalls of the stepped substrate, and the second hardmask layer thickness refers to a thickness of the hardmask layer at the bottom of the stepped substrate.

8. The method according to claim 7, further comprising:
coating the photoresist layer on the hardmask layer.

9. A method of designing a metasurface having a stepped substrate, comprising:
obtaining an operating wavelength range of the metasurface which is configured to generate a target optical lens;
according to the operating wavelength range, determining a material of the stepped substrate and a material of nanostructures, wherein the stepped substrate and the nanostructures form the metasurface;
selecting any wavelength from the operating wavelength range as a main wavelength of the operating wavelength range;
based on the main wavelength, calculating a shape and a size of the stepped substrate and determining the nanostructures in the metasurface;
based on the material of the stepped substrate and the material of the nanostructures, the calculated shape and the calculated size of the stepped substrate, a shape and a size of the nanostructures, forming the metasurface having the stepped substrate;
performing a full-wave simulation of the metasurface having the stepped substrate to obtain a simulation result;
when the simulation result shows that the metasurface having the stepped substrate is capable of realizing functions of the target optical lens, determining that the metasurface having the stepped substrate meets functional requirements of the target optical lens.

10. The method according to claim 9, wherein a step of “based on the main wavelength, calculating the shape and the size of the stepped substrate” comprises:
calculating a required phase for modulating light with the main wavelength;
according to the required phase for modulating the light with the main wavelength, calculating first phases which refer to phases of respective positions for phase design in the stepped substrate required for allowing the light with the main wavelength to transmit through the respective positions for phase design;
obtaining a refractive index of the stepped substrate for the light with the main wavelength; calculating substrate heights of the respective positions for phase design according to the refractive index of the stepped substrate for the light with the main wavelength, the first phases, and the main wavelength of the operating wavelength range, wherein substrate heights of adjacent positions for phase design are different, thereby forming the metasurface having the stepped substrate;
obtaining other wavelengths of the operating wavelength range, and obtaining a refractive index of the stepped substrate for light with the other wavelengths of the operating wavelength range; based on parameters, calculating second phases which refer to phases of the respective positions required for allowing the light with the other wavelengths of the operating wavelength range to transmit through the respective positions for phase design, wherein the parameters comprise the other wavelengths of the operating wavelength range, the refractive index of the stepped substrate for the light with the other wavelengths of the operating wavelength range, and the substrate heights of the respective positions for phase design.

11. The method according to claim 10, wherein a step of “according to the required phase for modulating the light with the main wavelength, calculating the first phases” comprises:
calculating the first phases by a following formula:
$${ϕ}_{c} ( x , y ) = mod ( {ϕ}_{design} ( x , y ) , 2 π )$$
wherein, ϕ_{c}(x, y) represents the first phases.

12. The method according to claim 10, wherein a step of “calculating the substrate heights of the respective positions for phase design according to the refractive index of the stepped substrate for the light with the main wavelength, the first phases, and the main wavelength of the operating wavelength range” comprises:
by a following formula, calculating the substrate heights of the respective positions for phase design:
$$\\ h ( x , y ) = \frac{{λ}_{c} {ϕ}_{c} ( x , y )}{2 π ( {n}_{c} - 1 )}$$
wherein, h(x, y) represents the substrate heights of the respective positions for phase design; ϕ_{c}(x, y) represents the first phases; n_{c} represents the refractive index of the stepped substrate for the light with the main wavelength.

13. The method according to claim 10, wherein a step of “based on the parameters, calculating the second phases” comprises:
calculating the second phases by a following formula:
$$\\ {ϕ}_{substrate} ( x , y , λ ) = \frac{2 π}{λ} ( n ( λ ) - 1 ) h ( x , y )$$
wherein, h(x, y) represents the substrate heights of the respective positions for phase design; n(λ) represents the refractive index of the stepped substrate for the light with the other wavelengths of the operating wavelength range; λ represents the other wavelengths of the operating wavelength range; ϕ_{substrate}(x, y, λ) represents the second phases.

14. The method according to claim 13, wherein a step of “based on the main wavelength, determining the nanostructures in the metasurface” comprises:
obtaining a designed phase of the metasurface for correcting chromatic aberration; calculating a required phase of the nanostructures according to the second phases and the designed phase;
performing an inquiry within a nanostructure database to obtain a target nanostructure with a phase closest to the required phase of the nanostructures, wherein a nanostructure-phase relationship is stored in the nanostructure database.

15. The method according to claim 14, wherein a step of “calculating the required phase of the nanostructures according to the second phases and the designed phase” comprises:
by a following formula, calculating the required phase of the nanostructures:
$$\\ {ϕ}_{total} ( x , y , λ ) = mod ( {ϕ}_{substrate} ( x , y , λ ) + {ϕ}_{nanostructure} ( x , y , λ ) , 2 π )$$
wherein, ϕₜₒₜₐₗ(x, y, λ) represents the designed phase of the metasurface for correcting chromatic aberration; ϕ_{nanostructure}(x, y, λ) represents the required phase of the nanostructures.

16. The method according to claim 14, wherein a step of “performing the inquiry within the nanostructure database to obtain the target nanostructure with the phase closest to the required phase of the nanostructures” comprises:
querying phases of predetermined nanostructures in the nanostructure database;
calculating differences between the required phase of the nanostructures and respective phases of the predetermined nanostructures, so as to obtain a smallest difference and a nanostructure among the predetermined nanostructures corresponding to the smallest difference; and taking the corresponding nanostructure as the target nanostructure with the phase closest to the required phase of the nanostructures.

17. A device for designing a metasurface having a stepped substrate, comprising:
an acquisition module, configured to obtain an operating wavelength range of the metasurface which is configured to generate a target optical lens; and configured to determine materials of the stepped substrate and nanostructures used to form the metasurface according to the operating wavelength range; and configured to select any wavelength from the operating wavelength range as a main wavelength of the operating wavelength range;
a first determination module, configured to calculate a shape and a size of the stepped substrate and determine the nanostructures in the metasurface based on the main wavelength;
a processing module, configured to form the metasurface having the stepped substrate based on the material of the stepped substrate and the material of the nanostructures, the calculated shape and the calculated size of the stepped substrate, a shape and a size of the nanostructures;
a simulation module, configured to perform a full-wave simulation of the metasurface having the stepped substrate to obtain a simulation result;
a second determination module, configured to determine that the metasurface having the stepped substrate meets functional requirements of the target optical lens when the simulation result shows that the metasurface having the stepped substrate is capable of realizing functions of the target optical lens.

18. A non-transitory computer-readable storage medium in which a computer program is stored, wherein the computer program is executed by a processor, so as to implement the method of designing the metasurface having the stepped substrate of claim 9.

19. An electronic device, comprising:
a memory, a processor and at least one program,
wherein the at least one program is stored in the memory and is configured to be executed by the processor, so as to implement the method of designing the metasurface having the stepped substrate of claim 9.

20. An optical lens, comprising the metasurface having the stepped substrate of claim 1.
